(19) United States
(12) Patent Application Publication
(10) Pub. No.: US 2012/0132997 A1
(43) Pub. Date: May 31, 2012

(54) SEMICONDUCTOR DEVICE AND MANUFACTURING METHOD THEREOF

(75) Inventor: Hirofumi TOKITA, Kanagawa (JP)

(73) Assignee: Renesas Electronics Corporation

(21) Appl. No.: 13/301,512

(22) Filed: Nov. 21, 2011

(30) Foreign Application Priority Data
Nov. 29, 2010 (JP) 2010-265403

(51) Int. Cl. H01L 27/092; H01L 21/336

(52) U.S. Cl. 257/368; 438/287; 257/E27.062; 257/E21.423

(57) ABSTRACT

To provide a technology capable of manufacturing a semiconductor device equipped with a HK/MG transistor having a gate insulating film comprised of a high-k material and a gate electrode comprised of a metal material and having stable operation characteristics. A film stack configuring an Nch gate stack structure is formed only in a region located in an active region surrounded with an element isolation portion and in which a gate of a core nMIS is to be formed in a later step is formed, while a film stack configuring a Pch gate stack structure is formed in a region other than the above region. This makes it possible to reduce a supply amount of oxygen atoms to be attracted from the element isolation portion to the region in which the gate of the core nMIS is to be formed.

### CROSS-REFERENCE TO RELATED APPLICATIONS

The disclosure of Japanese Patent Application No. 2010-265403 filed on Nov. 29, 2010 including the specification, drawings and abstract is incorporated herein by reference in its entirety.

### BACKGROUND

The invention relates to a semiconductor device and a manufacturing method thereof, in particular, to a technology effective when applied to a semiconductor device having a field effect transistor (HK (high-k)/MG (metal gate) transistor which will hereinafter be called “HK/MG transistor”) equipped with a gate insulating film comprised of a high-k material having a high dielectric constant and a gate electrode comprised of a metal material and manufacture of the semiconductor device described above.

With miniaturization of field effect transistors, a technology using, as a gate insulating film, a high-k film instead of conventionally used films such as SiO₂ film and SiON film has been studied in order to enhance the drive capability of field effect transistors by making use of a tunnel effect to suppress an increase in gate leakage current and at the same time, decreasing an equivalent oxide thickness (EOT) of the gate insulating film to improve the gate capacitance.

For example, U.S. Patent Application Laid-Open No. 2009/0152650 (Patent Document 1) discloses a technology of decreasing the length of a gate electrode on element isolation to the resolution limit of a lithography technology and thereby preventing reoxidation of a gate insulating film made of a high-k material.

C. M. Lai et. al., IEDM Tech. Dig., pp. 655-658 (2009) (Non-patent Document 1) describes a technology of forming a CMOSFET having a gate length of 28 nm by using a gate first process or a gate last process.

### [Patent Document 1] U.S. Patent Application Laid-Open No. 2009/0152650

### [Non-patent Document 1] C. M. Lai, C. T. Lin, L. W. Cheng, C. H. Hsu, J. T. Tseng, T. F. Chiang, C. H. Chou, Y. W. Chen, C. H. Yu, S. H. Hsu, C. G. Chen, Z. C. Lee, J. F. Lin, C. L. Yang, G. H. Ma, S. C. Chien, IEDM Technical Digest, pp. 655-658 (2009)

### SUMMARY

The investigation by the present inventors revealed that in a HK/MG transistor having a gate insulating film comprised of a high-k material and a gate electrode comprised of a metal material, a decrease in the gate width leads to a drastic increase in a threshold voltage. Such a drastic increase in a threshold voltage was particularly apparent in an n-channel type HK/MG transistor.

According to a further investigation made by the present inventors, it was presumed that that one of the causes for the above-described increase in threshold voltage in an n-channel type HK/MG transistor was supply of oxygen atoms to a gate insulating film from an insulating film configuring an element isolation. The present inventors therefore attempted to decrease an amount of oxygen atoms supplied to a gate insulating film from an element isolation portion by changing the condition of a manufacturing process, for example, heat treatment temperature or a material of the gate insulating film. It was however difficult to change the condition of a manufacturing process only for suppressing an increase in threshold voltage in an n-channel type HK/MG transistor and they failed to avoid the increase in threshold voltage in an n-channel type HK/MG transistor.

An object of the invention is to provide a technology capable of manufacturing a semiconductor device having a HK/MG transistor equipped with a gate insulating film comprised of a high-k material and a gate electrode comprised of a metal material and at the same time, having stable operating characteristics.

The above-described and the other objects and novel features of the invention will be apparent from the description herein and accompanying drawings.

One embodiment of a typical invention, among the inventions disclosed herein, will next be described briefly.

According to this embodiment, a semiconductor device has an n-channel type HK/MG transistor equipped with a gate insulating film comprised of a high-k material and a gate electrode comprised of a metal material. The n-channel type HK/MG transistor includes an element isolation portion formed in the main surface of a semiconductor substrate and containing an oxygen atom, an active region surrounded by the element isolation portion, a gate electrode formed over the active region and the element isolation portion successively and having a predetermined gate width, a HfLaON film formed between the gate electrode and the element isolation portion, a channel region formed in the active region below the gate electrode, and a source region and a drain region formed in the active regions on both sides of the gate electrode with the channel region therebetween. It further has a dummy gate which is formed in parallel to the gate electrode with a predetermined distance and a portion of which is formed over the active region between the element isolation portion and the end portion of the gate electrode in a gate length direction of the gate electrode and a HfAlOH film formed between the dummy gate and the active region.

In addition, this embodiment provides a manufacturing method of a semiconductor device by fabricating an re-channel type HK/MG transistor having a gate insulating film comprised of a high-k material and a gate electrode comprised of a metal material. The method includes a step of forming, around an active region, an element isolation portion made of an oxygen-containing insulating film, a step of forming a first oxide film on the surface of the active region and then forming a HfON film over the active region and the element isolation portion, a step of forming a Lao film over the HfON film in a first region having a predetermined width which is a region in the active region and in which a gate electrode is to be formed in a later step, a step of forming an AlO film over the HfON film in a second region which is a region in the active region but other than the first region and a third region in which the element isolation portion has been formed, a step of carrying out heat treatment to diffuse La contained in the LaO film into the HfON film of the first region to form a HfLaON film and diffuse Al contained in the AlO film into the HfON film of the second region and the third region to form a HfAlON film, a step of successively forming a TiN film and a polycrystalline Si film over the HfLaON film and the HfAlON film, a step of forming a gate electrode made of the polycrystalline Si film and the TiN film continuously over the active region and the element isolation portion by etching, forming a first gate insulating film made of the HfLaON film and the first oxide film between the gate electrode and the element isolation portion, and forming a second insulating film made of the HfAlON film between the gate electrode and the element isolation portion, and a step of introducing an impurity into active regions on both sides of the gate electrode to form a source region and a drain region, respectively.

An advantage available from one embodiment of the typical invention, among the inventions disclosed herein, will next be described briefly.

The invention makes it possible to provide a semiconductor device having stable operating characteristics while having a HK/MG transistor equipped with a gate insulating film comprised of a high-k material and a gate electrode comprised of a metal material.

### BRIEF DESCRIPTION OF THE DRAWINGS

FIG. 1 is an internal configuration diagram of a semiconductor device according to Embodiment 1 of the invention;

FIG. 2 is a fragmentary cross-sectional view, along a gate length direction, of an n-channel type HK/MG transistor and a p-channel type HK/MG transistor which are core transistors according to Embodiment 1 of the invention;

FIG. 3 is a fragmentary cross-sectional view, along the gate width direction, of the n-channel type HK/MG transistor and the p-channel type HK/MG transistor which are core transistors according to Embodiment 1 of the invention;

FIG. 4 is a fragmentary cross-sectional view, along the gate length direction, of an n-channel type HK/MG transistor and a p-channel type HK/MG transistor which are I/O transistors according to Embodiment 1 of the invention;

FIG. 5 is a fragmentary cross-sectional view of a resistive element according to Embodiment 1 of the invention;

FIGS. 6(a) and 6(b) are fragmentary plan views of an n-channel type HK/MG transistor according to Embodiment 1 of the invention, in which FIG. 6(a) is a fragmentary plan view after formation of a film stack configuring a gate of the n-channel type HK/MG transistor (before processing through dry etching) and FIG. 6(b) is a fragmentary plan view after processing of the film stack configuring the gate of the n-channel type HK/MG transistor through dry etching;

FIG. 7 is a fragmentary cross-sectional view showing a manufacturing step of the semiconductor device according to Embodiment 1 of the invention;

FIG. 8 is a fragmentary cross-sectional view showing the same position as that of FIG. 7 during a manufacturing step of the semiconductor device following the step of FIG. 7;

FIG. 9 is a fragmentary cross-sectional view showing the same position as that of FIG. 7 during a manufacturing step of the semiconductor device following the step of FIG. 8;

FIG. 10 is a fragmentary cross-sectional view showing the same position as that of FIG. 7 during a manufacturing step of the semiconductor device following the step of FIG. 9;

FIG. 11 is a fragmentary cross-sectional view showing the same position as that of FIG. 7 during a manufacturing step of the semiconductor device following the step of FIG. 10;

FIG. 12 is a fragmentary cross-sectional view showing the same position as that of FIG. 7 during a manufacturing step of the semiconductor device following the step of FIG. 11;

FIG. 13 is a fragmentary cross-sectional view showing the same position as that of FIG. 7 during a manufacturing step of the semiconductor device following the step of FIG. 12;

FIG. 14 is a fragmentary cross-sectional view showing the same position as that of FIG. 7 during a manufacturing step of the semiconductor device following the step of FIG. 13;

FIG. 15 is a fragmentary cross-sectional view showing the same position as that of FIG. 7 during a manufacturing step of the semiconductor device following the step of FIG. 14;

FIG. 16 is a fragmentary cross-sectional view showing the same position as that of FIG. 7 during a manufacturing step of the semiconductor device following the step of FIG. 15;

FIG. 17 is a fragmentary cross-sectional view showing the same position as that of FIG. 7 during a manufacturing step of the semiconductor device following the step of FIG. 16;

FIG. 18 is a fragmentary cross-sectional view showing the same position as that of FIG. 7 during a manufacturing step of the semiconductor device following the step of FIG. 17;

FIG. 19 is a fragmentary cross-sectional view showing the same position as that of FIG. 7 during a manufacturing step of the semiconductor device following the step of FIG. 18;

FIG. 20 is a fragmentary cross-sectional view showing the same position as that of FIG. 7 during a manufacturing step of the semiconductor device following the step of FIG. 19;

FIG. 21 is a fragmentary cross-sectional view showing the same position as that of FIG. 7 during a manufacturing step of the semiconductor device following the step of FIG. 20;

FIG. 22 is a fragmentary cross-sectional view showing the same position as that of FIG. 7 during a manufacturing step of the semiconductor device following the step of FIG. 21;

FIG. 23 is a fragmentary cross-sectional view showing the same position as that of FIG. 7 during a manufacturing step of the semiconductor device following the step of FIG. 22;

FIG. 24 is a fragmentary cross-sectional view showing the same position as that of FIG. 7 during a manufacturing step of the semiconductor device following the step of FIG. 23;

FIGS. 25(a) and 25(b) are fragmentary plan views of an n-channel type HK/MG transistor according to Embodiment 2 of the invention, in which FIG. 25(a) is a fragmentary plan view after formation of a film stack configuring a gate of the n-channel type HK/MG transistor (before processing through dry etching) and FIG. 25(b) is a fragmentary plan view after processing of the film stack configuring the n-channel type HK/MG transistor through dry etching;

FIG. 26 is a fragmentary plan view of an n-channel type HK/MG transistor according to Embodiment 3 of the invention;

FIG. 27 is a graph explaining the relationship between the threshold voltage (Vth) and gate width (W) of an n-channel type HK/MG transistor obtained by the present inventors;

FIG. 28 is a fragmentary plan view of an n-channel type HK/MG transistor investigated by the present inventors;

FIG. 29 is a graph showing, with a distance (SA) between a gate having an Nch gate stack structure obtained by the present inventors and an element isolation portion present along the gate length direction of this gate as a parameter, the relationship between a threshold voltage (Vth) of an n-channel type HK/MG transistor and a width (ODx) of the element isolation portion (IS), which is located along a gate length direction (first direction) of the gate having an Nch gate stack structure, along the gate length direction (first direction);

FIG. 30 is a graph showing, with a distance (SA) between a gate having an Nch gate stack structure obtained by the present inventors and an element isolation portion present along the gate length direction of this gate as a parameter, the relationship between a gate leakage current (Jg) of the n-channel type HK/MG transistor and a width (ODx) of the element isolation portion (IS), which is located along a gate length direction (first direction) of the gate having an Nch gate stack structure, along the gate length direction (first direction);

FIG. 31 is a fragmentary cross-sectional view showing a manufacturing step of a semiconductor device according to Embodiment 4 of the invention;

FIG. 32 is a fragmentary cross-sectional view showing the same position as that of FIG. 31 during a manufacturing step of the semiconductor device following the step of FIG. 31;

FIG. 33 is a fragmentary cross-sectional view showing the same position as that of FIG. 31 during a manufacturing step of the semiconductor device following the step of FIG. 32;

FIG. 34 is a fragmentary cross-sectional view showing the same position as that of FIG. 31 during a manufacturing step of the semiconductor device following the step of FIG. 33;

FIG. 35 is a fragmentary cross-sectional view showing the same position as that of FIG. 31 during a manufacturing step of the semiconductor device following the step of FIG. 34;

FIG. 36 is a fragmentary cross-sectional view showing the same position as that of FIG. 31 during a manufacturing step of the semiconductor device following the step of FIG. 35; and

FIG. 37 is a fragmentary cross-sectional view showing the same position as that of FIG. 31 during a manufacturing step of the semiconductor device following the step of FIG. 36.

### DETAILED DESCRIPTION

In the following embodiments, a description will be made after divided in a plurality of sections or in a plurality of embodiments if necessary for convenience's sake. These sections or embodiments are not independent from each other, but in a relation such that one is a modification example, details, or a complementary description of a part or whole of the other one unless otherwise specifically indicated.

In the following embodiments, when a reference is made to the number of elements (including the number, value, amount, and range), the number is not limited to the specific number but can be greater than or less than the specific number unless otherwise specifically indicated or principally apparent that the number is limited to the specific number. Moreover, in the following embodiments, it is needless to say that constituting elements (including elemental steps) are not always essential unless otherwise specifically indicated or principally apparent that the element is essential. Similarly, in the following embodiments, when a reference is made to the shape or positional relationship of the constituting elements, that substantially analogous or similar to it is also embraced unless otherwise specifically indicated or principally apparent that it is not. This also applies to the above-described value and range.

In the drawings used in the following embodiments, some plan views may be hatched in order to facilitate viewing of them. In the below-described embodiments, MISFET (metal insulator semiconductor field effect transistor) representative of field effect transistors is abbreviated as MIS, p-channel MISFET is abbreviated as pMIS, and n channel MISFET is abbreviated as nMIS. In the below-described embodiments, the term “wafer” mainly means an Si (silicon) single crystal wafer, but it also means an SOI (silicon on insulator) wafer, an insulating film substrate for forming an integrated circuit thereover, or the like. The shape of the wafer is not limited to disc or substantially disc, but it may be square or rectangular.

In the following embodiments, the term “gate” or “gate structure” means a film stack of a gate insulating film and a gate electrode and it is discriminated from a gate electrode.

In all the drawings for describing the following embodiments, like members of a function will be identified by like reference numerals and overlapping descriptions will be omitted. The embodiments of the invention will hereinafter be described specifically referring to drawings.

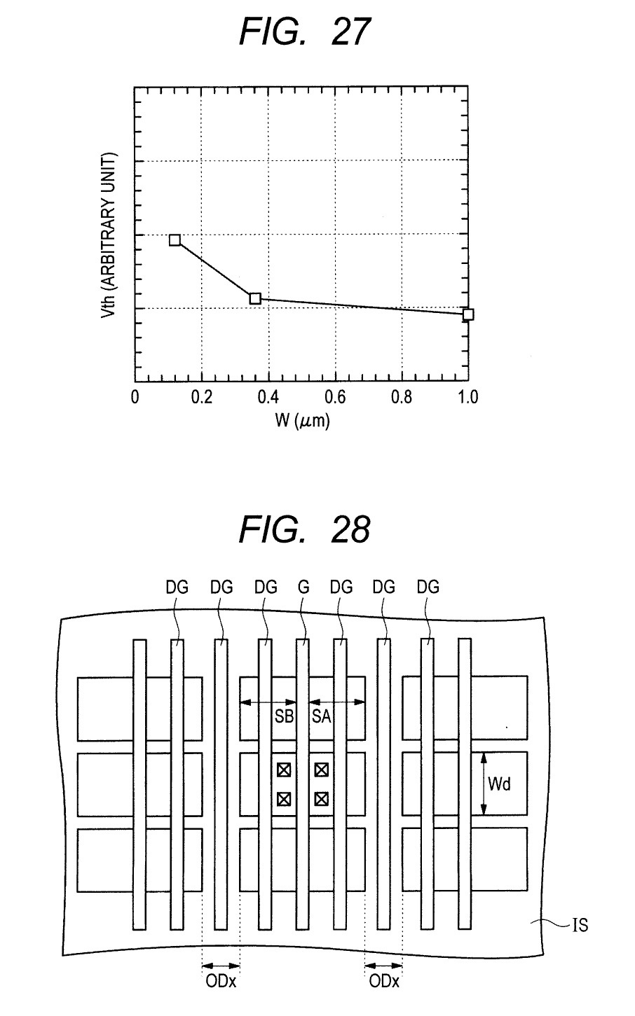

The cause of an increase in threshold voltage due to narrowing of a channel of an n-channel type HK/MG transistor found by the present inventors will next be described referring to FIGS. 27 to 30, because it is presumed to elucidate the structure of the HK/MG transistor of the present embodiment further.

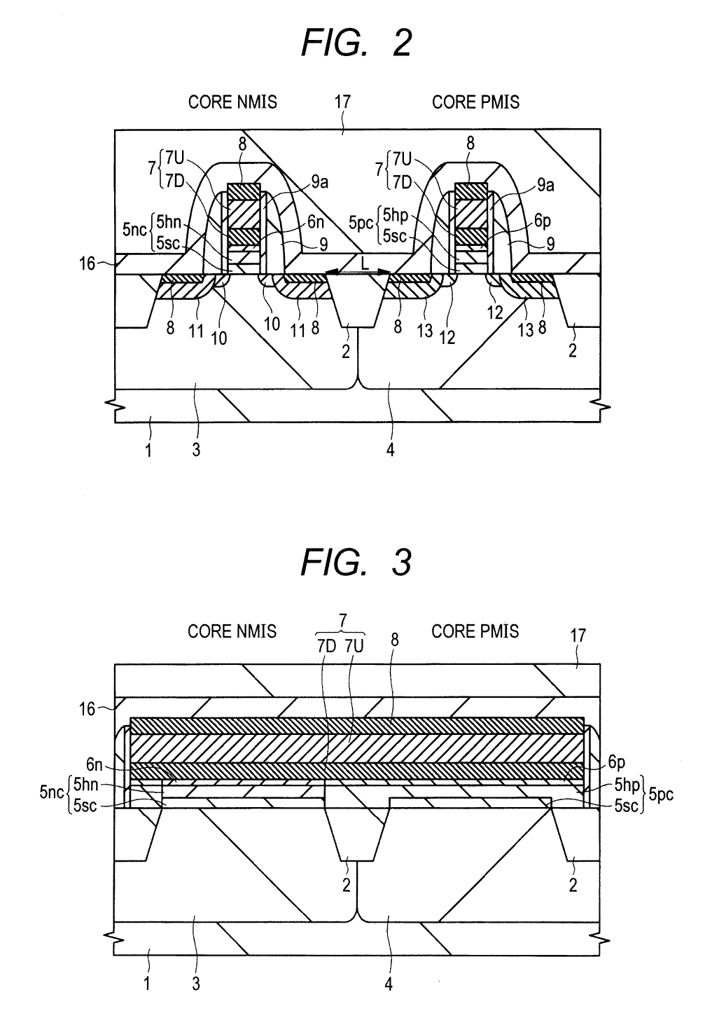

The gate structure of an n-channel type HK/MG transistor described herein is the same as that of an n-channel type HK/MG transistor described later referring to FIGS. 2 to 4. It has a gate insulating film made of a film stack of a SiO₂ film and a HfLaON film (La-containing hafnium oxynitride film) and a gate electrode formed on the gate insulating film and made of a film stack of a TiN film and a polycrystalline Si film.

The gate structure of this n-channel type HK/MG transistor is, on the other hand, different from that of a p-channel type HK/MG transistor. The gate structure of the p-channel type HK/MG transistor is the same as that of a p-channel type HK/MG transistor described later referring to FIGS. 2 to 4. It has a gate insulating film made of a film stack of a SiO₂ film and a HfAlON film (Al-containing hafnium oxynitride film or a hafnium-based insulating film containing La at a lower concentration than the above-described HfLaON film of the n-channel type HK/MG transistor or containing no La) and a gate electrode formed on the gate insulating film and made of a film stack of a TiN film and a polycrystalline Si film.

The gate structure (gate insulating film and gate electrode) of the n-channel type HK/MG transistor and the gate structure (gate insulating film and gate electrode) of the p-channel type HK/MG transistor are therefore distinguished by referring to the former as an Nch gate stack structure and referring to the latter as a Pch gate stack structure. The term “Nch gate stack structure” or “Pch gate stack structure” embraces both a structure having a SiO₂ film below the gate insulating film and a structure having no such a film therebelow.

FIG. 27 is a graph for describing the relationship between the threshold voltage (Vth) and the gate width (W) of the n-channel type HK/MG transistor.

As shown in FIG. 27, when the gate width of the re-channel type HK/MG transistor becomes 0.4 μm or less, a narrow channel effect meaning an increase in the threshold voltage of the n-channel type HK/MG transistor appears. In general, examples of the cause for this narrow channel effect include widening, in a width direction, of a depletion layer at the end portion of a channel region. Described specifically, a depletion layer widens in a width direction at the end portion of a channel region, which is presumed to increase the charge amount of the depletion layer to be controlled at the gate electrode, leading to an increase in a threshold voltage. It is also cited as a cause of an increase in the threshold voltage that diffusion of an impurity for a channel stopper below an element isolation portion into a channel region increases the threshold voltage at the end portion of the channel region, which decreases an effective channel width.

(1) Investigation by the present inventors has however revealed that in the n-channel type HK/MG transistor, the thickness of the gate insulating film becomes greater than the original thickness due to oxygen atoms supplied thereto from an element isolation portion, resulting in an increase in the threshold voltage.

(2) In addition, the present inventors have found that as the distance from the end portion of the gate of the n-channel type HK/MG transistor to the element isolation portion present in the gate length direction of this gate becomes shorter or as the width of the element isolation portion present in the gate length direction of the n-channel type HK/MG transistor which is the width along the gate length direction of the element isolation portion becomes greater, the threshold voltage of the n-channel type HK/MG transistor increases. Such phenomena will be described next referring to FIGS. 28 to 30.

FIG. 28 is a fragmentary plan view showing a portion of a circuit equipped with the n-channel type HK/MG transistor investigated by the present inventors.

As shown in FIG. 28, a gate G of an Nch gate stack structure contributing to the circuit operation has, on both sides thereof, a plurality of dummy gates DG arranged in parallel to this gate G with a predetermined distance. These dummy gates DG are provided, for example, in order to realize microfabrication of the gate G of an Nch gate stack structure and they are not coupled to wirings which electrically couple a plurality of semiconductor elements to each other. In short, these dummy gates DG are not electrically coupled to any semiconductor element.

Some of the dummy gates DG are formed only over the element isolation portion IS, while some are formed continuously, similar to the gate G of the Nch gate stack structure, over the element isolation portion IS and an active region of a semiconductor substrate surrounded with the element isolation portion IS (extend over the element isolation portion IS from the active region of the semiconductor substrate).

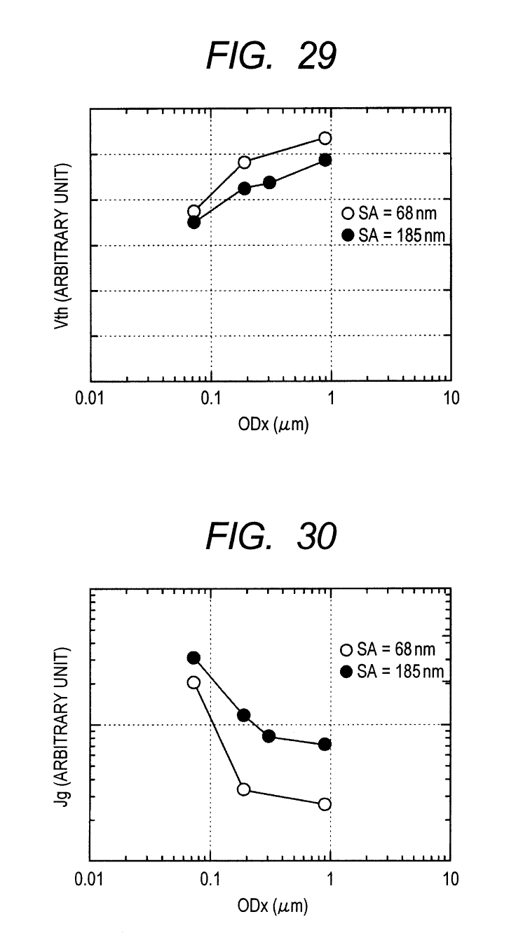

FIG. 29 is a graph showing, with a distance (SA) between the end portion of the gate G of the Nch gate stack structure and the element isolation portion IS present in the gate length direction of this gate G as a parameter, the relationship between a threshold voltage (Vth) of the n-channel type HK/MG transistor and a width (ODx) of the element isolation portion (IS), which is located along a gate length direction (first direction) of the gate G of the Nch gate stack structure, along the gate length direction (first direction).

As illustrated in FIG. 29, with a decrease in the distance SA from the end portion of the gate G to the element isolation portion IS or with an increase in the width ODx of the element isolation portion IS along the gate length direction, the threshold voltage of the n-channel type HK/MG transistor increases. On the other hand, such an increase in the threshold voltage has scarcely been found in a p-channel type HK/MG transistor.

FIG. 30 is a graph showing, with a distance (SA) between the end portion of a gate G of an Nch gate stack structure and an element isolation portion IS present along the gate length direction of this gate as a parameter, the relationship between a gate leakage current (Jg) of the n-channel type HK/MG transistor and a width (ODx) of the element isolation portion (IS), which is located along a gate length direction (first direction) of the gate having the Nch gate stack structure, along the gate length direction (first direction).

As shown in FIG. 30, with a decrease in the distance SA from the end portion of the gate G to the element isolation portion IS or with an increase in the width ODx of the element isolation portion IS along the gate length direction, the gate leakage current of the n-channel type HK/MG transistor decreases. On the other hand, such a decrease in the gate leakage current has scarcely been found in the p-channel type HK/MG transistor.

After formation of the gate G of the Nch gate stack structure, there is a route through which oxygen atoms are supplied from the element isolation portion IS to a portion of the gate G formed over the element isolation portion IS, but there is no oxygen-atom supplying route which can explain the supply amount of oxygen atoms to a gate insulating film, which varies depending on the distance SA or SB from the end portion of the gate G to the element isolation portion IS or the width ODx of the element isolation portion IS along the gate length direction. Accordingly, it is presumed that oxygen atoms have already been attracted to the gate insulating film before the gate G of the Nch gate stack structure is formed. This suggests that with a decrease in the distance SA or SB from the end portion of the gate G to the element isolation portion IS or with an increase in the width ODx of the element isolation portion IS along the gate length direction, an amount of oxygen atoms supplied to the gate insulating film increases, leading to an increase in the threshold voltage as shown above in FIG. 29 and a decrease in the gate leakage current as described above in FIG. 30.

(3) Further, the p-channel type HK/MG transistor showed almost no sign of such an increase in threshold voltage and a decrease in gate leakage current, as described above. A major difference between the gate G of the Nch gate stack structure of the n-channel type HK/MG transistor and the gate G of the Pch gate stack structure of the p-channel type HK/MG transistor is a material of a metal film (cap film) formed over the gate insulating film for controlling the threshold voltage. Described specifically, in the gate G of the Nch gate stack structure, a cap film made of, for example, a LaO film is formed on the gate insulating film in order to add La thereto, while in the gate G of the Pch gate stack structure, a cap film made of, for example, an AlO film is formed on the gate insulating film in order to add Al thereto. In the gate G of the Nch gate stack structure, supply of oxygen atoms to the gate insulating film from the element isolation portion IS is presumed to be promoted by the metal film (cap film) formed on the gate insulating film.

In the invention, therefore, an increase in the threshold voltage of the n-channel type HK/MG transistor is suppressed by decreasing, prior to formation of the gate G of the Nch gate stack structure of the n-channel type HK/MG transistor, a supply amount of oxygen atoms to be attracted to the gate insulating film from the element isolation portion IS.

### Embodiment 1

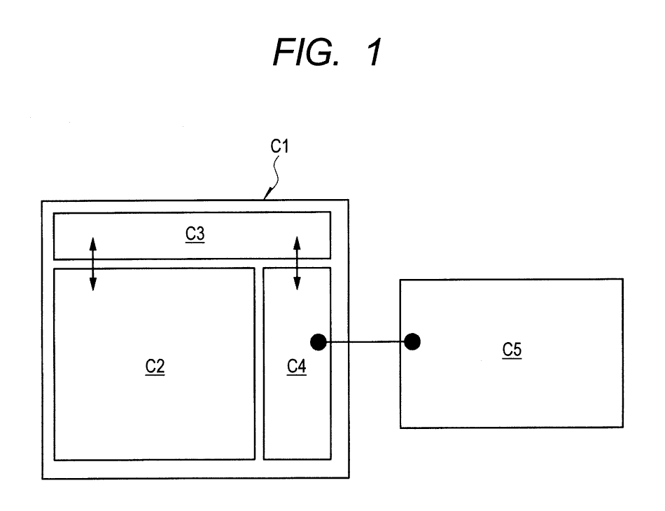

FIG. 1 is an internal configuration diagram of a semiconductor device according to Embodiment 1.

A semiconductor device C1 is comprised of a plurality of circuits such as a memory circuit C2, a processor circuit C3, and an I/O (input/output) circuit C4. The memory circuit C2 stores data and programs therein, the processor circuit C3 conducts arithmetic processing or control processing of the data. The data and programs are passed between the memory circuit C2 and the processor circuit C3. In addition, the data are passed between the processor circuit C3 and the I/O circuit C4 and they are sent to a peripheral device C5 through the I/O circuit C4. Further, voltage necessary for the circuit operation is intermittently supplied, as a signal, to the memory circuit C2 and the processor circuit C3 via the I/O circuit C4.

The memory circuit C2 has a plurality of memory transistors; the processor circuit C3 has a plurality of core transistors; and the I/O circuit C4 has a plurality of I/O transistors. The core transistors include an n-channel type HK/MG transistor and a p-channel type HK/MG transistor and the I/O transistors include an n-channel type HK/MG transistor and a p-channel type HK/MG transistor.

The gate electrode of the n-channel type HK/MG transistor of the core transistor has the same structure as that of the n-channel type HK/MG transistor of the I/O transistor. A voltage applied to the I/O transistor is however higher than that applied to the core transistor so that the gate insulating film of the n-channel type HK/MG transistor of the I/O transistor is thicker than that of the gate insulating film of the n-channel type HK/MG transistor of the core transistor. Similarly, the gate electrode of the p-channel type HK/MG transistor of the core transistor has the same structure as that of the p-channel type HK/MG transistor of the I/O transistor. A voltage applied to the I/O transistor is however higher than that applied to the core transistor so that the gate insulating film of the p-channel type HK/MG transistor of the I/O transistor is thicker than that of the gate insulating film of the p-channel type HK/MG transistor of the core transistor.

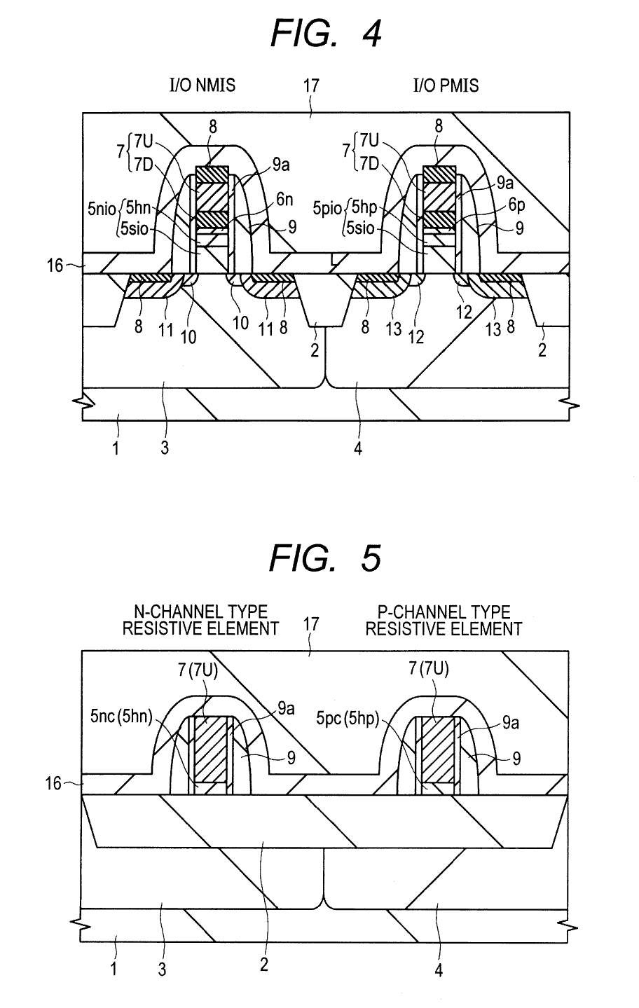

Next, the structure of each of a core transistor, an I/O transistor, and a resistive element according to Embodiment 1 will next be described referring to FIGS. 2 to 5. FIG. 2 is a fragmentary cross-sectional view, along a gate length direction, of an n-channel type HK/MG transistor and a p-channel type HK/MG transistor which are core transistors according to Embodiment 1, FIG. 3 is a fragmentary cross-sectional view, along a gate width direction, of a circuit in which a gate of the n-channel type HK/MG transistor and a gate of the p-channel type HK/MG transistor, each of the core transistor according to Embodiment 1, have been coupled to each other, FIG. 4 is a fragmentary cross-sectional view, along a gate length direction, of an n-channel type HK/MG transistor and a p-channel type HK/MG transistor which are I/O transistors according to Embodiment 1; and FIG. 5 is a fragmentary cross-sectional view of an n-channel type resistive element and a p-channel type resistive element formed in the processor circuit according to Embodiment 1.

First, the configuration of the n-channel type HK/MG transistor (which will hereinafter be called “core nMIS”) of the core transistor and the p-channel type HK transistor (which will hereinafter be called “core pMIS”) of the core transistor according to Embodiment 1 will be described referring to FIGS. 2 and 3.

A semiconductor substrate 1 has, in the main surface thereof on which the core nMIS and the core pMIS according to Embodiment 1 are to be formed, an element isolation portion 2. The element isolation portion 2 has a function of preventing interference between elements formed on the semiconductor substrate 1. It is formed, for example, by using STI (shallow trench isolation) which is a process of forming a trench in the semiconductor substrate 1 and then burying an insulating film in the trench. An active region separated by this element isolation portion 2 is a core nMIS formation region or a core pMIS formation region. The insulating film buried in the trench is, for example, a TEOS film formed using plasma CVD (chemical vapor deposition) with TEOS (tetra ethyl ortho silicate; Si (OC₂H₅) ₄) and ozone as source gases, a SiO₂ film formed using high density plasma CVD, or a polysilazane (SiH NH) film. The width L of the element isolation portion 2 is set at at least about 80 nm in order to prevent interference between elements.

In the core nMIS formation region, the semiconductor substrate 1 has, in the main surface thereof, a p well 3 which is a semiconductor region. In the core pMIS formation region, the semiconductor substrate 1 has, in the main surface thereof, an n well 4 which is a semiconductor region. The p well 3 has a p type impurity such as B introduced therein and the n well 4 has an n type impurity such as P or As introduced therein.

Next, the configuration of the core nMIS will be described.

The p well 3, formed in the main surface of the semiconductor substrate 1 in the core nMIS formation region, has a gate insulating film 5nc on the p well.

This gate insulating film 5nc is composed mainly of, for example, a high dielectric constant film 5hn which has a higher dielectric constant than SiO₂. As the high dielectric constant film 5hn, a hafnium-based insulating film such as HfOₓ film, HfON film, HfSiOₓ film, or HfSiON film is used. This hafnium-based insulating film contains a metal element, for example, La for controlling a work function to obtain a core nMIS having a desired threshold voltage. It is therefore possible to give HfLaON as a typical example of the material configuring the high dielectric constant film 5hn.The high dielectric constant film 5hn has a thickness of, for example, approximately 1 nm.

The semiconductor substrate 1 and the high dielectric constant film 5hn have therebetween an oxide film 5sc, for example, a SiO₂ film. Direct contact between the semiconductor substrate 1 and the high dielectric constant film 5hn may presumably cause a reduction in the mobility of the core nMIS, but insertion of the oxide film 5sc between the semiconductor substrate 1 and the high dielectric constant film 5hn can prevent this reduction in the mobility. The oxide film 5sc has a thickness of, for example, approximately 1 nm.

The gate insulating film 5nc has thereon a cap film 6n. This cap film 6n is, for example, a LaO film. It is formed in order to add, to the hafnium-based insulating film configuring the high dielectric constant film 5hn, a metal element, that is, La for obtaining a core nMIS having a desired threshold voltage. La is given as an example of the metal element to be added to the hafnium-based insulating film configuring the high dielectric constant film 5hn, but another metal element is usable. Accordingly, examples of the film usable as the cap film 6n include La₂O₅ film, La film, MgO film, Mg film, BiSr film, SrO film, Y film, Y₂O₃ film, Ba film, BaO film, Se film, and ScO film. Incidentally, all the metal elements configuring the cap film 6n are sometimes added to the high dielectric constant film 5hn.

The cap film 6n has thereon a gate electrode 7. This gate electrode 7 has a stack structure of a lower gate electrode 7D and an upper gate electrode 7U. The lower gate electrode 7D is comprised of, for example, a TiN film but is not limited thereto. The lower gate electrode 7D may be comprised of, for example, a TaN film, a TaSiN film, a TiAlN film, a HfN film, a NiₓSi₁₋ₓ, film, a PtSi film, a NiₓTa₁₋ₓSi film, a NiₓPt₁₋ₓSi film, a HfSi film, a WSi film, a IrₓSi₁₋ₓ film, a TaGe film, a TaCx film, a Mo film, or a W film. The lower gate electrode 7D has a thickness of, for example, approximately from 5 to 20 nm. The upper gate electrode 7U is comprised of, for example, a polycrystalline Si film having an impurity of approximately 1×10²⁰ cm⁻³ introduced therein. The upper gate electrode 7U has a thickness of, for example, approximately 30 to 80 nm.

The gate electrode 7 has thereon a silicide film 8. This silicide film 8 is, for example, a NiSi film or a PtSi film.

The film stack of the gate electrode 7 and the film stack of the gate insulating film 5nc each has, on the sidewalls on both sides thereof, an offset sidewall 9a and a sidewall 9, each made of an insulating film and the former one being placed inner than the latter one. The semiconductor substrate 1 (p well 3) rightly below these offset side wall 9a and the sidewall 9 has therein n type diffusion regions 10 which are semiconductor regions and these n type diffusion regions 10 have, on the outside thereof, n type diffusion regions 11. The n type diffusion regions 10 and the n type diffusion regions 11 have an n type impurity such as P or As introduced therein. The concentration of the n type impurity is higher in the n type diffusion regions 11 than in the n type diffusion regions 10. These n type diffusion regions 10 and n type diffusion regions 11 configure a source region and a drain region of the core nMIS having an LDD (lightly doped drain) structure. Although not illustrated, the semiconductor substrate 1 (p well 3) rightly below the gate electrode 7 and between the source region and the drain region has therein a channel region having an impurity introduced therein in order to control the threshold value of the core nMIS.

The n type diffusion regions 11 have, in the surface thereof, a silicide film 8 formed by the same step as that of the silicide film 8 on the gate electrode 7.

Next, the configuration of the core pMIS will be described.

The n well 4, formed in the main surface of the semiconductor substrate 1 in the core pMIS formation region, has a gate insulating film 5pc thereon.

This gate insulating film 5pc is composed mainly of, for example, a high dielectric constant film Shp which has a higher dielectric constant than SiO₂. As the high dielectric constant film 5hp, a hafnium-based insulating film such as HfOₓ film, HfON film, HfSiOₓ film, or HfSiON film is used. This hafnium-based insulating film contains a metal element, for example, Al for controlling a work function to obtain a core pMIS having a desired threshold voltage. It is therefore possible to give HfAlON as a typical example of the material configuring the high dielectric constant film 5hp. The high dielectric constant film Shp has a thickness of, for example, approximately 1 nm. The high dielectric constant film Shp contains La at a lower concentration than the high dielectric constant film 5hn or the high dielectric constant film Shp contains no La.

The semiconductor substrate 1 and the high dielectric constant film Shp have therebetween an oxide film 5sc, for example, a SiO₂ film. Direct contact between the semiconductor substrate 1 and the high dielectric constant film Shp may presumably cause a reduction in the mobility of the core pMIS, but insertion of the oxide film 5sc between the semiconductor substrate 1 and the high dielectric constant film Shp can prevent the reduction in the mobility. The oxide film 5sc has a thickness of, for example, approximately 1 nm.

The gate insulating film 5pc has thereon a cap film 6p. This cap film 6p is, for example, an AlO film. It is formed in order to add, to the hafnium-based insulating film configuring the high dielectric constant film 5hp, a metal element, that is, Al for obtaining a core pMIS having a desired threshold voltage. Incidentally, an AlO film is given as an example of the cap film 6p, but it may be replaced with an Al film. All the metal elements configuring the cap film 6p are sometimes added to the high dielectric constant film 5hp.

The cap film 6p has thereon a gate electrode 7 and this gate electrode 7 has thereon a silicide film 8. These gate electrode 7 and silicide film 8 have the same configuration as that of the gate electrode 7 and the silicide film 8 of the above-described core nMIS, respectively.

The film stack of the gate electrode 7 and the film stack of the gate insulating film 5pc have, on the sidewalls on both sides thereof, an offset sidewall 9a and a sidewall 9, each made of an insulating film and the former one being placed inner than the latter one. The semiconductor substrate 1 (n well 4) rightly below these offset side wall 9a and sidewall 9 have therein p type diffusion regions 12 which are semiconductor regions and these p type diffusion regions 12 have, on the outside thereof, p type diffusion regions 13. These p type diffusion regions 12 and p type diffusion regions 13 have a p type impurity such as B introduced therein. The concentration of the p type impurity is higher in the p type diffusion regions 13 than in the p type diffusion regions 12. These p type diffusion regions 12 and p type diffusion regions 13 configure a source region and a drain region of the core pMIS having an LDD structure. Although not illustrated, the semiconductor substrate 1 (n well 4) rightly below the gate electrode 7 and between the source region and the drain region has therein a channel region having an impurity introduced therein in order to control the threshold value of the core pMIS.

The p type diffusion regions 13 have, in the surface thereof, a silicide film 8 formed by the same step as that of the silicide film 8 on the gate electrode 7. Further, the core nMIS and the core pMIS are covered with a Si₃N₄ film 16 and an interlayer insulating film 17.

Next, the configuration of each of an n-channel type HK/MG transistor and a p-channel HK transistor of the I/O transistor according to Embodiment 1 (which will hereinafter be called “I/O nMIS” and “I/O pMIS”, respectively) will be described referring to FIG. 4.

The configuration of the I/O nMIS is similar to the above-described configuration of the core nMIS, but the oxide film 5sio configuring the gate insulating film 5 nio of the I/O nMIS is thicker than that of the oxide film 5sc configuring the gate insulating film 5nc of the core nMIS. For example, the thickness of the oxide film 5sio formed between the semiconductor substrate 1 and a high dielectric constant film 5hn is, for example, from 2 to 6 nm.

The configuration of the I/O pMIS is also similar to the above-described configuration of the core pMIS, but the oxide film 5sio configuring the gate insulating film 5pio of the I/O pMIS is thicker than the oxide film 5sc configuring the gate insulating film 5pc of the gate insulating film 5pio of the core pMIS. For example, the thickness of the oxide film 5sio formed between the semiconductor substrate 1 and a high dielectric constant film 5hp is, for example, from 2 to 6 nm.

Next, the configuration of each of the n-channel type resistive element and the p-channel type resistive element formed in the processor circuit according to Embodiment 1 will next be described referring to FIG. 5.

The configuration of the n-channel type resistive element makes use of that of the above-described core nMIS and it is similar to the configuration of the core nMIS except that it has none of the oxide film 5sc, the cap film 6n, and the lower gate electrode 7D of the gate electrode 7 and it is formed over the element isolation portion 2. Similarly, the configuration of the p-channel type resistive element makes use of that of the above-described core pMIS and it is similar to the configuration of the core pMIS except that it has none of the oxide film 5sc, the cap film 6p, and the lower gate electrode 7D of the gate electrode 7 and it is formed over the element isolation portion 2. Incidentally, the n-channel type resistive element and the p-channel type resistive element may have the oxide film 5sc similar to the core nMIS and the core pMIS (not illustrated), respectively.

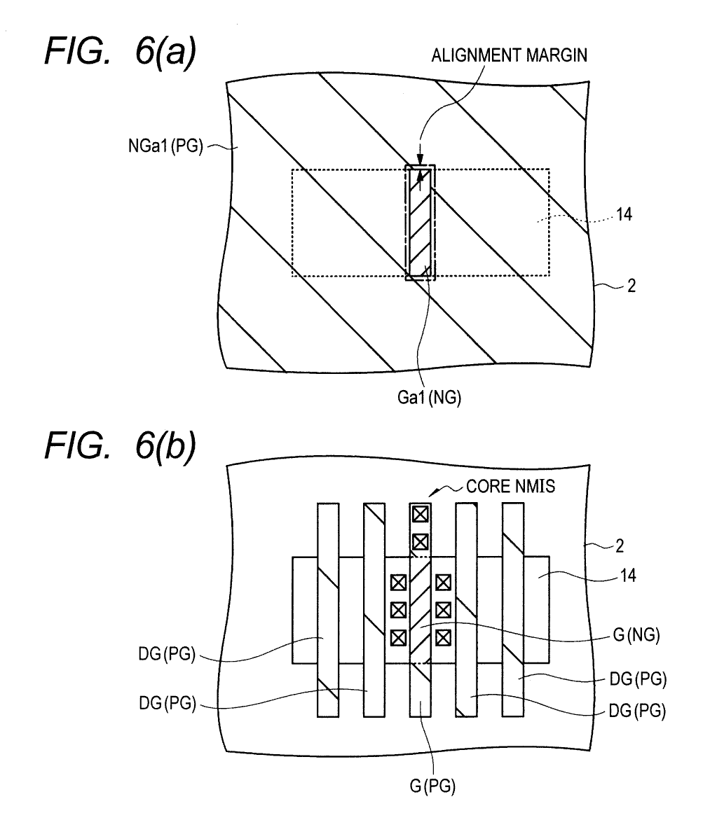

A planar layout of the core nMIS according to Embodiment 1 will next be described referring to FIGS. 6(a) and 6(b). FIG. 6 (a) is a fragmentary plan view after formation of a film stack configuring a gate of the core nMIS (before processing through dry etching) and FIG. 6(b) is a fragmentary plan view after processing of the film stack configuring the core nMIS through dry etching. An application example of the invention to the core nMIS is described here, but needless to say, the invention can also be applied to the I/O nMIS.

As shown in FIG. 6(a), in a region Ga1 which is located in the active region (region indicated by a dotted line) 14 surrounded with the element isolation portion 2 and in which a gate of the core nMIS contributing to a circuit operation will be formed in a later step, various films configuring the Nch gate stack structure NG such as the gate insulating film 5nc (film stack of the oxide film 5sc and the high dielectric constant film 5hn), the cap film 6n, and gate electrode materials are formed successively in the order from the bottom. For example, a SiO₂ film, a HfLaON film, a LaO film, a TiN film, and a polycrystalline Si film are therefore stacked one after another.

On the other hand, in a region NGa1 which is a region other than the region Ga1 in which the gate of the core nMIS is to be formed, various films configuring the Pch gate stack structure PG such as the gate insulating film 5pc (film stack of the oxide film 5sc and the high dielectric constant film 5hp), the cap film 6p, and gate electrode materials are formed successively in the order from the bottom. For example, a SiO₂ film, a HfAlON film, an AlO film, a TiN film, and a polycrystalline Si film are therefore stacked one after another.

A boundary between the region Ga1 and the region NGa1 is, in a gate width direction of the core nMIS, on a boundary between the element isolation portion 2 and the active region 14 and in a gate length direction of the core nMIS, on the end portion of the gate G of the core nMIS formed by processing of the film stack through dry etching.

The planar shape of each of the gate G and the dummy gate DG of the core nMIS formed by processing the film stack through dry etching is shown in FIG. 6(b).

The gate G of the core nMIS located in the active region 14 surrounded with the element isolation portion 2 has an Nch gate stack structure NG composed of a gate insulating film 5nc (film stack of an oxide film 5sc and a high dielectric constant film 5hn), a cap film 6n, and a gate electrode 7 (film stack of a lower gate electrode 7D and an upper gate electrode 7U) which are of the core nMIS shown above in FIGS. 2 and 3. The gate G of the core nMIS located in the active region 14 therefore has, for example, the gate insulating film 5nc made of a SiO₂ film and a HfLaON film, the cap film 6n made of a LaO film, and the gate electrode 7 made of a film stack of a TiN film and a polycrystalline Si film.

The gate G of the core nMIS on the element isolation portion 2 and a plurality of dummy gates DG which are formed on both sides of the gate G of the core nMIS and arranged in parallel to the gate G with a predetermined distance each has a Pch gate stack structure PG composed of a gate insulating film 5pc (a high dielectric constant film 5hp or a film stack of an oxide film 5sc and the high dielectric constant film 5hp), a cap film 6p, and a gate electrode 7 (film stack of a lower gate electrode 7D and an upper gate electrode 7U), which are of the core pMIS shown above in FIGS. 2 and 3. The gate G and the dummy gates DG of the core nMIS which have run over the element isolation portion 2 therefore have, for example, the gate insulating film 5pc made of a HfAlON film or a film stack of an SiO₂ film and a HfLaON film, the cap film 6n made of an AlO film, and the gate electrode 7 made of a film stack of a TiN film and a polycrystalline Si film.

Thus, only in the region Ga1 which is located in the active region 14 surrounded with the element isolation portion 2 and in which the gate G of the core nMIS is to be formed, the gate insulating film 5nc (film stack of an oxide film 5sc and a high dielectric constant film 5hn), the cap film 6n, and the gate electrode materials configuring the Nch gate stack structure NG are formed. On the other hand, in the region NGa1 on the element isolation portion 2 which region is other than the region Ga1 and in which the gate G and dummy gates DG of the core nMIS are to be formed, the gate insulating film 5pc (a high dielectric constant film Shp or a film stack of an oxide film 5sc and a high dielectric constant film 5hp), the cap film 6p, and the gate electrode materials for configuring the Pch gate stack structure PG are formed. This makes it possible to reduce the supply amount of oxygen atoms to be attracted from the element isolation portion 2 to the gate insulating film 5nc in the region Ga1 in which the gate G of the core nMIS is to be formed. As a result, it is possible to prevent oxidation of the gate insulating film 5nc and thereby suppressing an increase in the threshold voltage of the core nMIS.

Formation of a film stack configuring the Nch gate stack structure NG only in the region Ga1 which is located in the active region 14 surrounded with the element isolation portion 2 and in which the gate G of the core nMIS is to be formed, as indicated by a solid line in FIG. 6(a), is most effective for reducing the supply amount of oxygen atoms to be attracted from the element isolation portion 2 to the gate insulating film 5nc of the region Gal in which the gate G of the core nMIS is to be formed. In this case, however, in the actual manufacturing steps of a semiconductor device, there is a danger of the film stack configuring the Pch gate stack structure PG included in a portion of the gate G of the core nMIS, depending on the misalignment or processing accuracy, which may prevent normal operation of the core nMIS.

In the actual manufacturing steps of a semiconductor device, as shown by a dotted-dashed line in FIG. 6(a), a film stack configuring the Nch gate stack structure NG is formed at a greater width than that of the region Ga1 located in the active region 14 surrounded with the element isolation portion 2 and in which the gate G of the core nMIS is to be formed while taking into consideration an alignment margin in the manufacturing procedure of a semiconductor device. This means that in the gate width direction of the core nMIS, the boundary between the region Ga1 and the region NGa1 is placed at a position shifted from the boundary between the element isolation portion 2 and the active region 14 to the side of the element isolation portion 2 by a dimension predetermined in consideration of the alignment margin (on the element isolation portion 2) and in the gate length direction of the core nMIS, the boundary is placed at a position shifted from the end portion of the gate G to the side of the element isolation portion 2 by a dimension predetermined in consideration of the alignment margin (on the active region between the end portion of the gate G of the core nMIS and the element isolation portion 2).

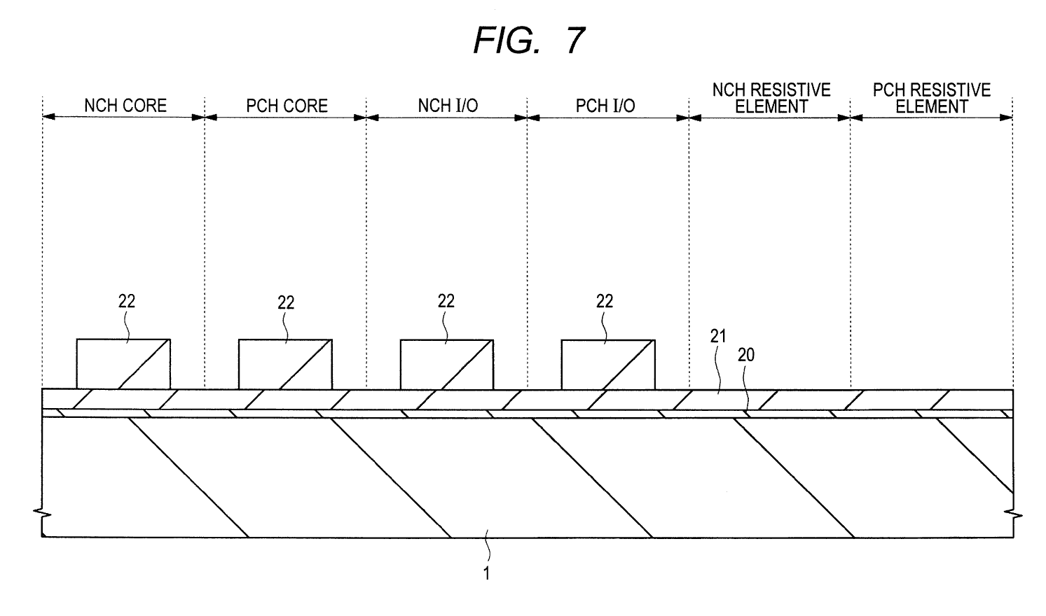

A manufacturing method of a semiconductor device according to Embodiment 1 will next be described in the order of steps referring to FIGS. 7 to 24. FIGS. 7 to 24 are fragmentary cross-sectional views showing, among circuit elements to be formed in the semiconductor device, a core nMIS (Nch core), a core pMIS (Pch nore), an I/O nMIS (Nch I/O), an I/O pMIS (Pch I/O), an n-channel type resistive element (Nch resistive element), and a p-channel type resistive element (Pch resistive element).

First, as shown in FIG. 7, a semiconductor substrate (in this stage, a thin semiconductor sheet having a substantially circular plane and called “semiconductor wafer”) 1 obtained by introducing a p type impurity such as B into, for example, a single crystal Si is prepared. Then, on the main surface of the semiconductor substrate 1, a SiO₂ film 20 and a Si₃N₄ film 21 are formed successively. The SiO₂ film 20 has a thickness of, for example, about 10 nm and the Si₃N₄ film 21 has a thickness of, for example, about 80 nm. Then, a resist pattern 22 for covering therewith a region which will be an active region is formed by photolithography.

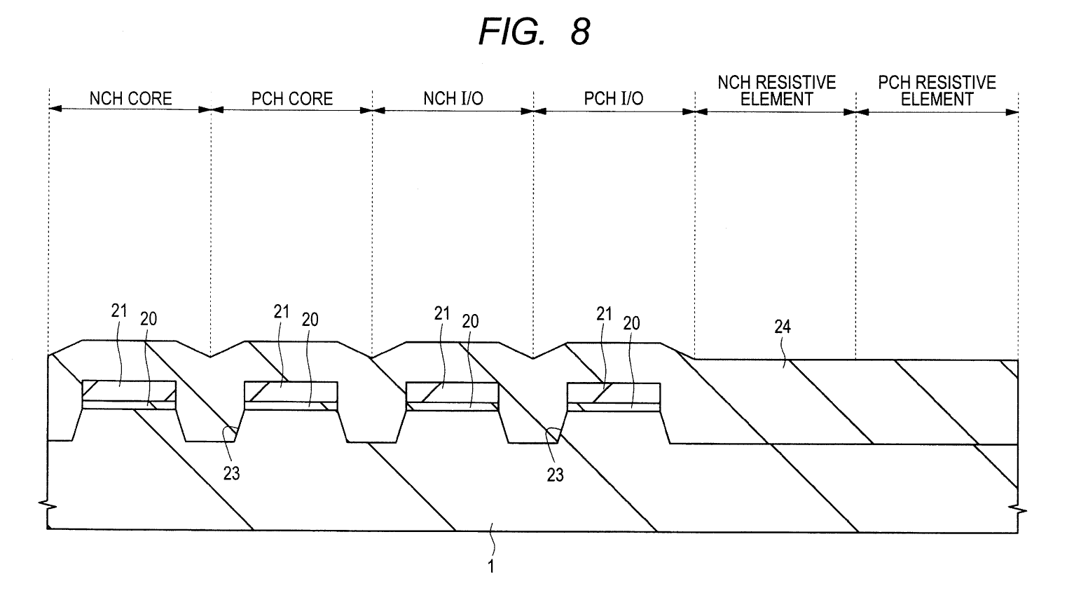

Next, as illustrated in FIG. 8, with the resist pattern 22 as a mask, the Si₃N₄ film 21, the SiO₂ film 20, and the semiconductor substrate 1 exposed from the resist pattern 22 are removed successively by using, for example, dry etching to form a trench 23 in the semiconductor substrate 1. Then, the resist pattern 22 is removed. After nitriding treatment and oxidation treatment of the inner wall of the trench 23, an oxide film 24 is formed on the main surface of the semiconductor substrate 1 to bury the trench 23 therewith. This oxide film is, for example, a TEOS film formed using plasma CVD with TEOS and ozone as source gases, a SiO₂ film formed using high-density plasma CVD, or a polysilazane film. Then, heat treatment is performed. This heat treatment is performed, for example, at 1100° C.

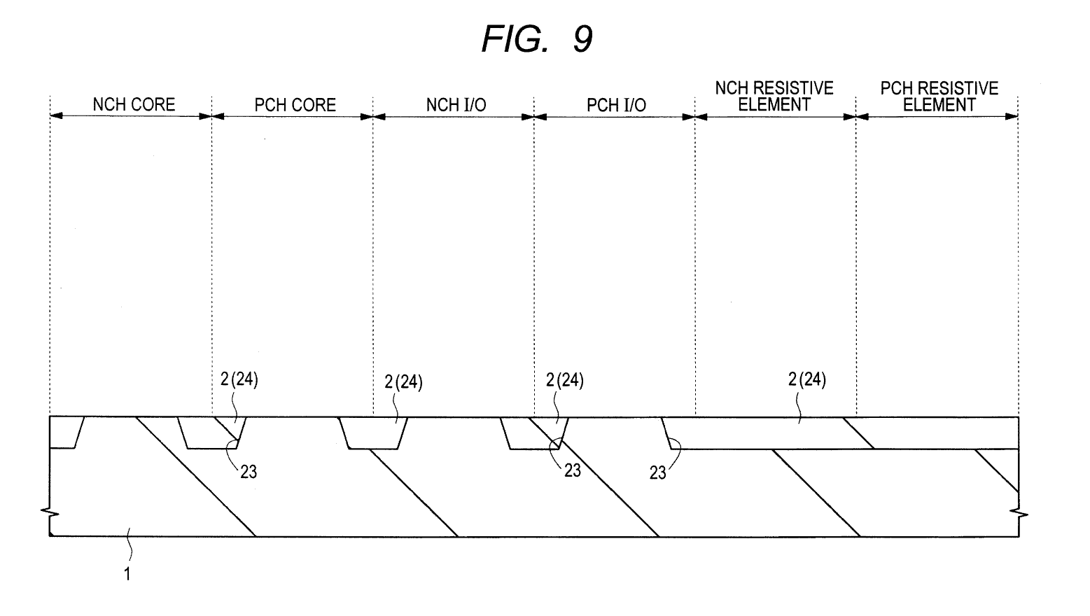

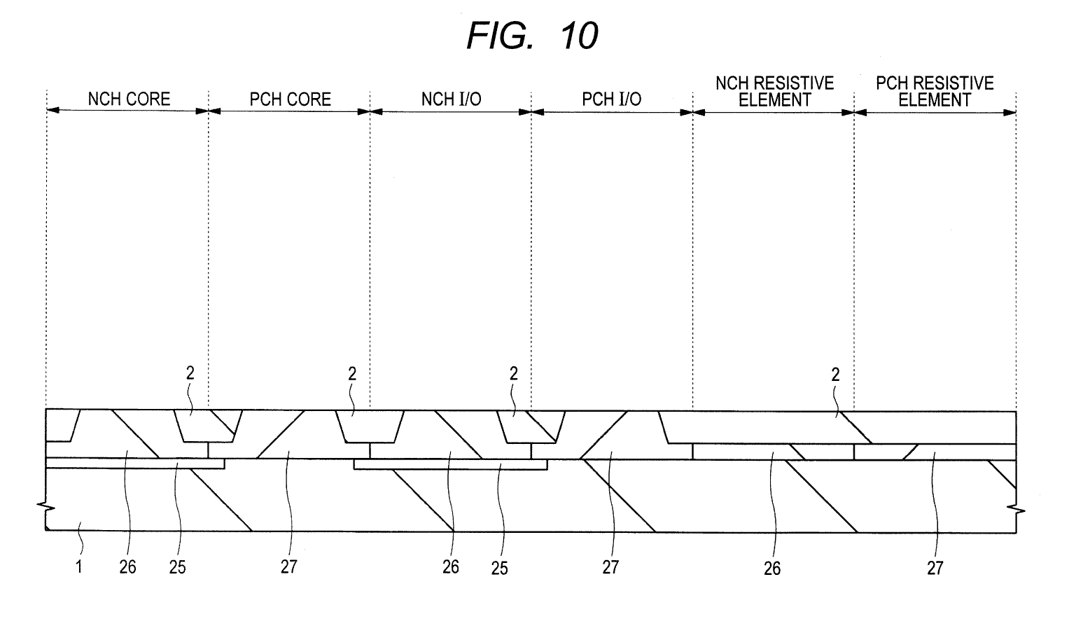

Next, as illustrated in FIG. 9, the surface of the oxide film 24 is polished using, for example, CMP (chemical mechanical polishing) to bury the oxide film 24 in the trench 23, thereby forming an element isolation portion 2. By this element isolation portion 2, active regions are separated and a core nMIS formation region, a core pMIS formation region, an I/O nMIS formation region, and an I/O pMIS formation region are formed.

Next, as illustrated in FIG. 10, an n type impurity is selectively introduced into the semiconductor substrate 1 in the core nMIS formation region and the I/O nMIS formation region by using ion implantation to form a buried n well 25. Then, a p type impurity is selectively introduced into the semiconductor substrate 1 in the core nMIS formation region and the I/O nMIS formation region to form a p well 26. Similarly, an n type impurity is selectively introduced into the semiconductor substrate 1 in the core pMIS formation region and the I/O pMIS formation region by using ion implantation to form an n well 27.

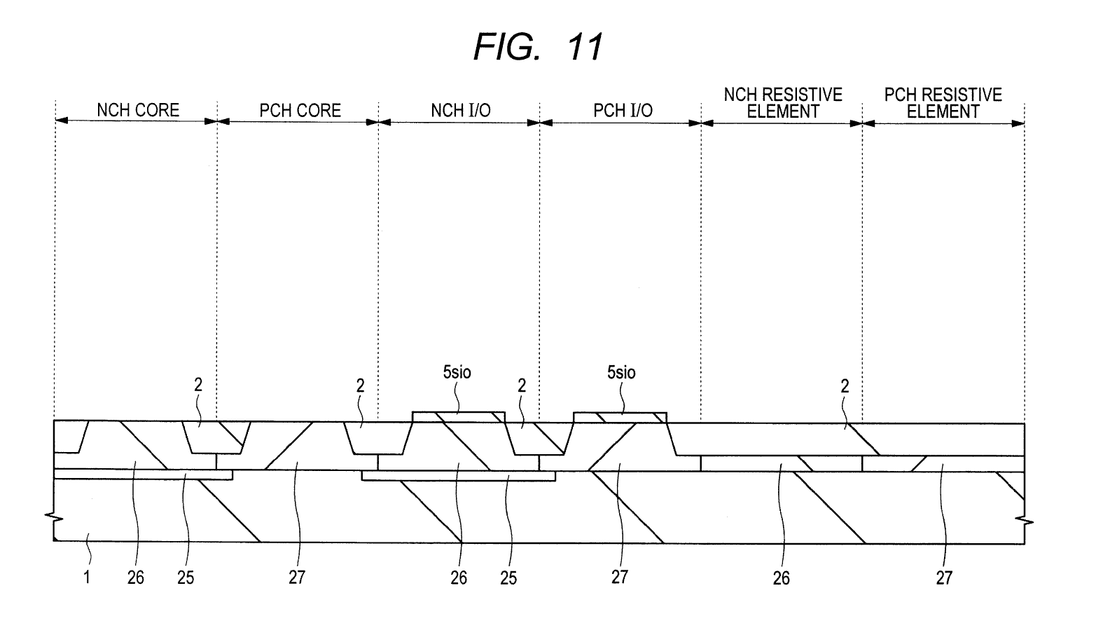

Next, as illustrated in FIG. 11, an oxide film 5sio is formed on the main surface of the semiconductor substrate 1 by using, for example, thermal oxidation. The oxide film 5sio has a thickness of, for example, approximately from 2 to 6 nm. Then, the oxide film 5sio is removed from the core nMIS formation region and the core pMIS formation region to leave the oxide film 5sio formed in the I/O nMIS formation region and the I/O pMIS formation region.

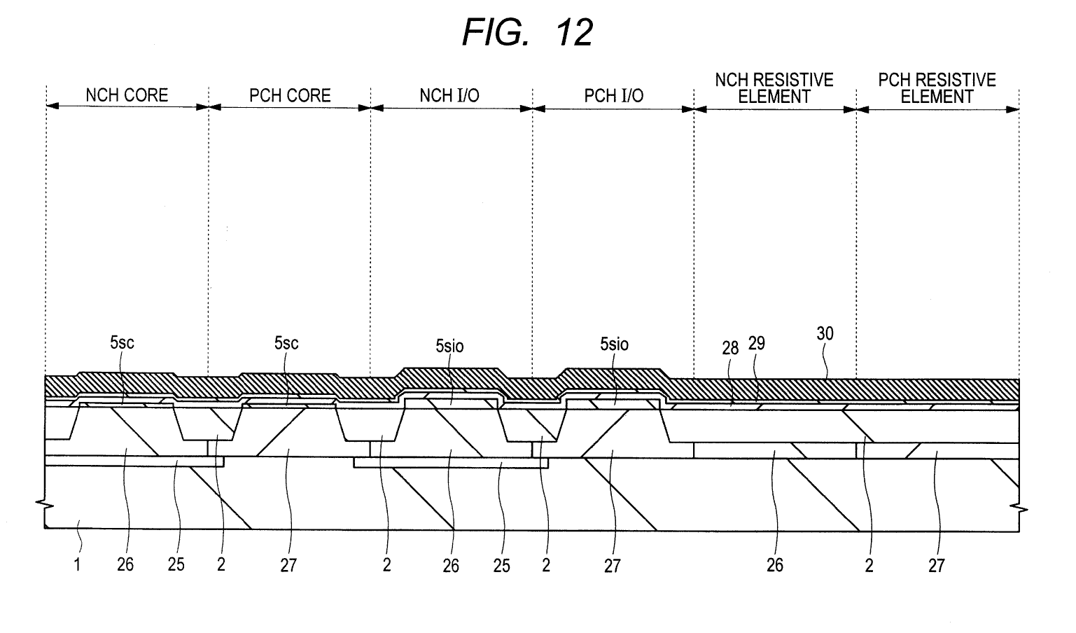

Next, as illustrated in FIG. 12, an oxide film 5sc is formed on the main surface of the semiconductor substrate 1 by using, for example, thermal oxidation. The oxide film 5sc has a thickness of, for example, approximately 1 nm. As a result, the oxide film 5sc is formed on the main surface of the semiconductor substrate 1 in the core nMIS formation region and the core pMIS formation region and the oxide film 5sio is formed on the main surface of the semiconductor substrate 1 in the I/O nMIS formation region and the I/O pMIS formation region.

Then, for example, a HfON film 28 is formed on the main surface of the semiconductor substrate 1. The HfON film 28 is formed using, for example, CVD or ALD (atomic layer deposition) and it has a thickness of, for example, about 1 nm. The HfON film 28 may be replaced with a hafnium-based insulating film such as HfSiON film, HfSiO film, or HfO₂ film.

After nitriding treatment, for example, an AlO film 29 (cap film 6p) is deposited on the HfON film 28. The AlO film 29 is formed, for example, by sputtering and it has a thickness of, for example, approximately from 0.1 to 1.5 nm. Then, for example, a TiN film 30 is deposited on the AlO film 29. The TiN film 30 is formed using, for example, sputtering and it has a thickness of, for example, approximately from 5 to 15 nm.

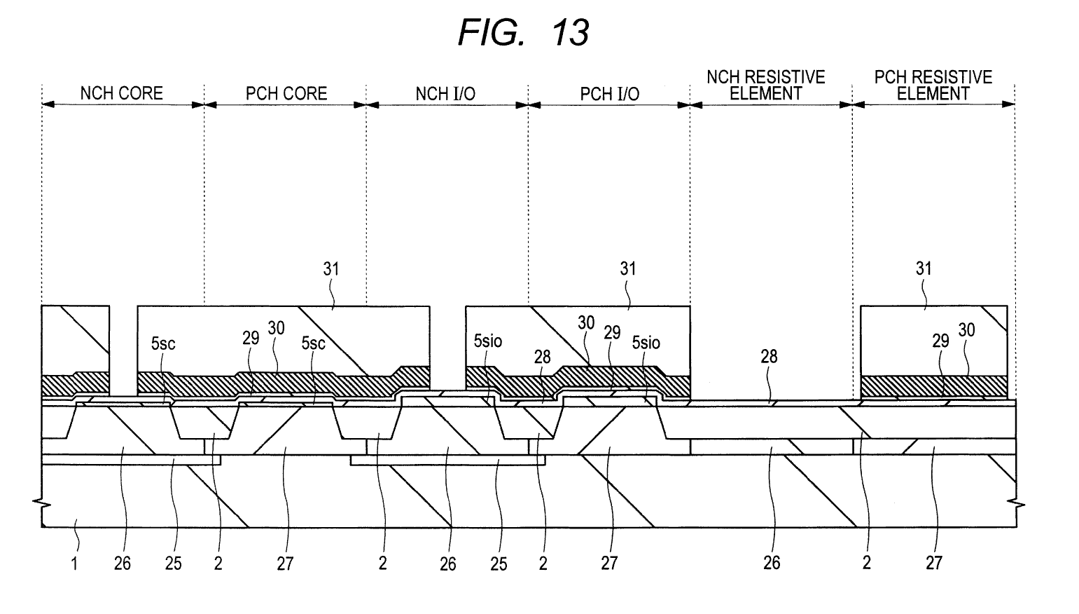

Next, as illustrated in FIG. 13, a resist pattern 31 for covering therewith each of the core pMIS formation region, the I/O pMIS formation region, and the p-channel type resistive element formation region is formed using photolithography. In this step, the core nMIS formation region except a region which is located in the active region surrounded with the element isolation portion 2 and in which the gate of the core nMIS is to be formed in a later step and the I/O nMIS formation region except a region which is located in the active region surrounded with the element isolation portion 2 and in which a gate of the I/O nMIS is to be formed in a later step are also covered with the resist pattern 31. Accordingly, the end portion of the resist pattern 31 in the core nMIS formation region is, in the gate width direction of the core nMIS, on a boundary between the element isolation portion 2 and the active region and in the gate length direction, on the end portion of the gate of the core nMIS to be formed in a later step. Similarly, the end portion of the resist pattern 31 in the I/O nMIS formation region is, in the gate width direction of the I/O nMIS, on a boundary between the element isolation portion 2 and the active region and, in the gate length direction, on the end portion of the gate of the I/O nMIS to be formed in a later step.

As described above, in the actual manufacturing steps of a semiconductor device, the end portion of the resist pattern 31 in the core nMIS formation region is shifted in consideration of an alignment margin in the manufacturing procedure of the semiconductor device. It is, in the gate width direction of the core nMIS, shifted from the boundary between the element isolation portion 2 and the active region to the side of the element isolation portion 2 by a predetermined dimension and is placed on the element isolation portion 2, while it is, in the gate length direction, shifted from the end portion of the gate of the core nMIS to be formed in a later step to the side of the element isolation portion 2 and is placed on the active region. Similarly, in consideration of an alignment margin in the manufacturing procedure of a semiconductor device, the end portion of the resist pattern 31 in the I/O nMIS formation region is, in the gate width direction of the I/O nMIS, shifted from the boundary between the element isolation portion 2 and the active region to the side of the element isolation portion 2 by a predetermined dimension and is placed on the element isolation portion 2, while it is, in the gate length direction, shifted from the end portion of the gate of the I/O nMIS to be formed in a later step to the side of the element isolation portion 2 by a predetermined dimension and is placed on the active region.

Then, after removal of the AlO film 29 and the TiN film 30 exposed from the resist pattern 31 with the resist pattern 31 as a mask, the resist pattern 31 is removed. As a result of this removal, the AlO film 29 and the TiN film 30 remain in the core pMIS formation region, the I/O pMIS formation region, and the p-channel type resistive element formation region. Further, the AlO film 29 and the TiN film 30 also remain in the core nMIS formation region and the I/O nMIS formation region except some areas (areas in which the gate of the core nMIS and the gate of the I/O nMIS are to be formed in a later step).

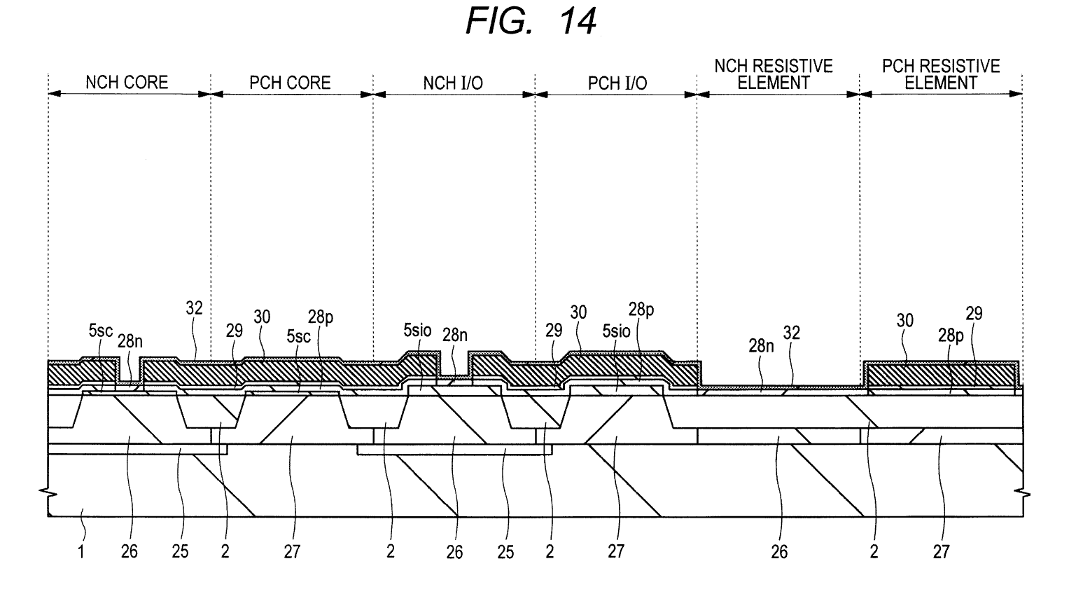

Then, as illustrated in FIG. 14, for example, a LaO film 32 (cap film 6n) is deposited on the main surface of the semiconductor substrate 1. The LaO film 32 is formed using, for example, sputtering and it has a thickness of, for example, from approximately 0.1 to 1.5 nm. Then, heat treatment is performed. This heat treatment is performed, for example, at 1000° C. for 10 seconds. This heat treatment causes thermal diffusion of Al from the AlO film 29 to the HfON film 28 to convert the HfON film 28 in the core pMIS formation region, the I/O pMIS formation region, and the p-channel type resistive element formation region into a HfAlON film 28p (high dielectric constant film 5hp). Also in the core nMIS formation region and the I/O nMIS formation region, the HfON film 28 is converted into a HfAlON film 28p (high dielectric constant film Shp) except some areas (areas in which the gate of the core nMIS and the gate of the I/O nMIS are to be formed in a later step).

In addition, this heat treatment causes thermal diffusion of La from the LaO film 32 to the HfON film 28 and converts the HfON film 28 into a HfLaON film 28n (high dielectric constant film 5hn) in some areas of the core nMIS formation region and the I/O nMIS formation region (areas in which the gate of the core nMIS and the gate of the I/O nMIS are to be formed in a later step) and in the n-channel type resistive element formation region.

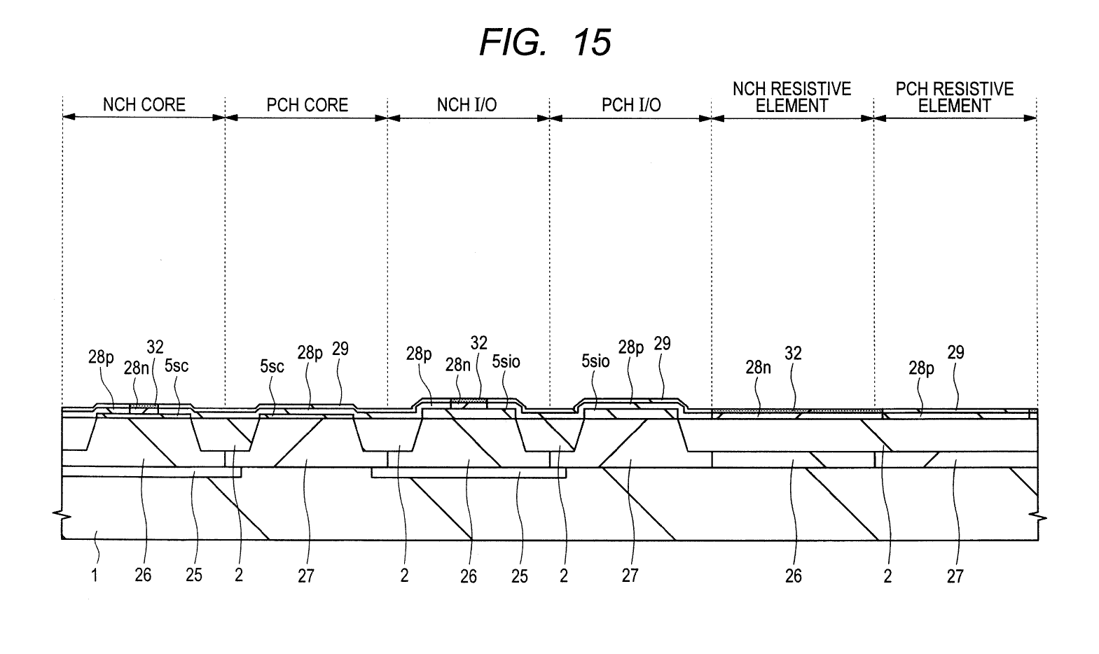

Next, as illustrated in FIG. 15, the TiN film 30, the AlO film 29, and the LaO film 32 are removed. The TiN film 30, the AlO film 29, and the LaO film 32 may be removed completely, but in FIG. 15, the AlO film 29 and the LaO film 32 are not removed completely and are left partially.

As a result of this removal, a gate insulating film (gate insulating film 5nc) made of the oxide film 5sc and the HfLaON film 28n is formed in an area of the core nMIS formation region (area where the gate of the core nMIS is to be formed in a later step) and a gate insulating film (gate insulating film 5pc) made of the oxide film 5sc and the HfAlON film 28p is formed in the core pMIS formation region and the core nMIS formation region except the above-described area (where the gate of the core nMIS is to be formed in a later step).

In addition, a gate insulating film (gate insulating film 5nio) made of the oxide film 5sio and the HfLaON film 28n is formed in an area of the I/O nMIS formation region (area where the gate of the I/O nMIS is to be formed in a later step) and a gate insulating film (gate insulating film 5pio) made of the oxide film 5sio and the HfAlON film 28p is formed in the I/O pMIS formation region and the I/O nMIS formation region except the above-described area (area where the gate of the I/O nMIS is to be formed in a later step).

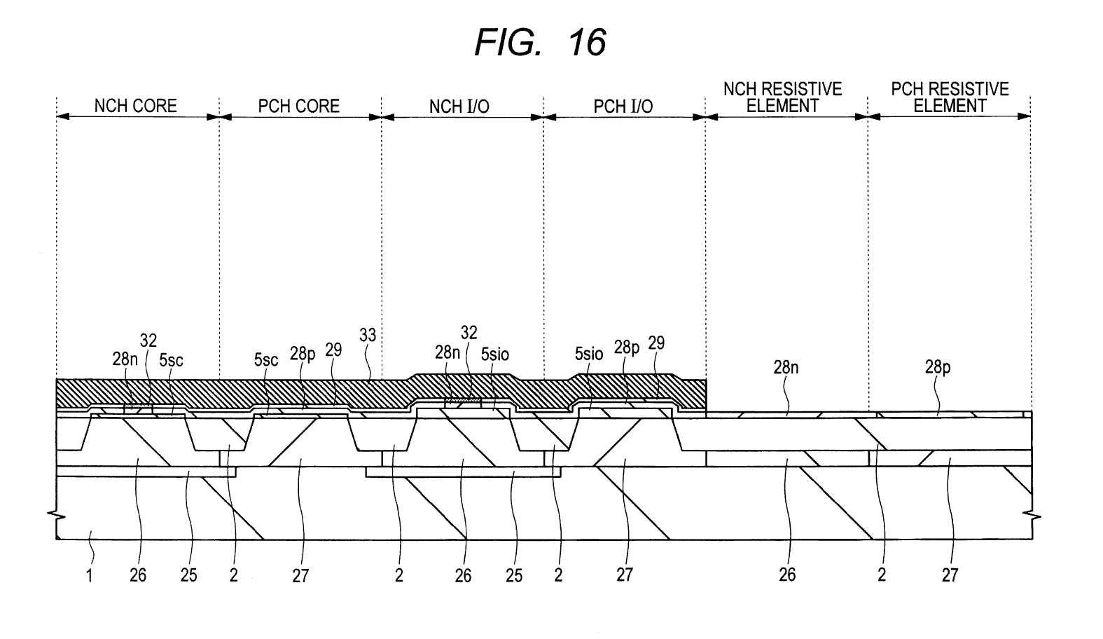

Next, as illustrated in FIG. 16, for example, a TiN film 33 is deposited on the main surface of the semiconductor substrate 1. The TiN film 33 is formed using, for example, sputtering and it has a thickness of, for example, from approximately 5 to 20 nm. Then, a resist pattern (not illustrated) covering therewith the core nMIS formation region, the core pMIS formation region, the I/O nMIS formation region, and the I/O pMIS formation region is formed using photolithography. Then, with this resist pattern as a mask, the TiN film 33, the AlO film 29, and the LaO film 32 in the n-channel type resistive element formation region and the p-channel type resistive element formation region exposed from the resist pattern are removed. The resist pattern is thereafter removed. It is not necessary to remove the AlO film 29 and the LaO film 32 completely, but in FIG. 16, the AlO film 29 and the LaO film 32 are removed.

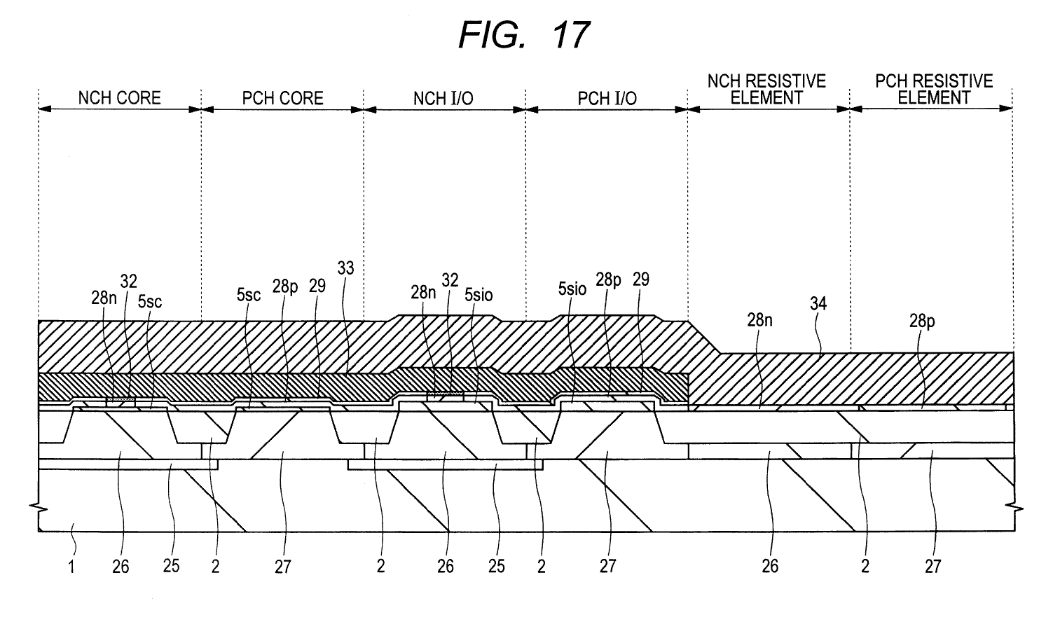

Next, as illustrated in FIG. 17, for example, a polycrystalline Si film 34 is deposited on the main surface of the semiconductor substrate 1. The polycrystalline Si film 34 is formed using, for example, CVD and it has a thickness of, for example, from approximately 30 to 80 nm. Then, heat treatment is performed. This heat treatment is performed, for example, at 1000° C. for 10 seconds.

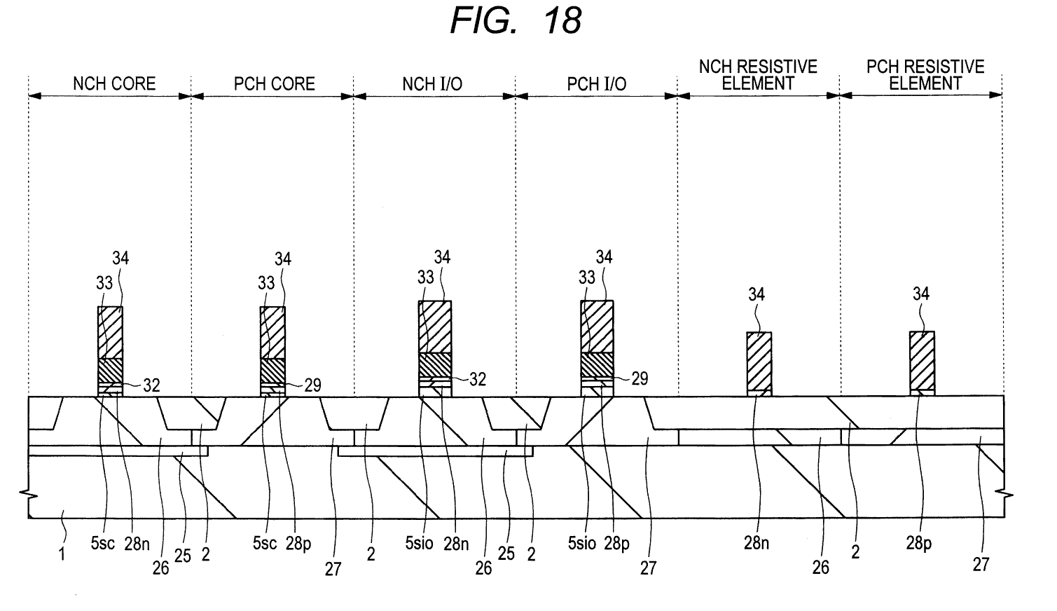

Next, as illustrated in FIG. 18, the polycrystalline Si film 34, the TiN film 33, the LaO film 32, the AlO film 29, the HfAlON film 28p, the HfLaON film 28n, the oxide film 5sio, and the oxide film 5sc are processed using photolithography and etching.

As a result of this processing, in the core nMIS formation region, a gate having an Nch stack gate structure comprised of a gate insulating film (gate insulating film 5nc) made of a film stack of the oxide film 5sc and the HfLaON film 28n (high dielectric constant film 5hn), the LaO film 32 (cap film 6n), and a gate electrode (gate electrode 7) made of a film stack of the TiN film 33 (lower gate electrode 7D) and the polycrystalline Si film 34 (upper gate electrode 7U) is formed. In addition, in the core pMIS formation region, a gate having a Pch stack gate structure comprised of a gate insulating film (gate insulating film 5pc) made of a film stack of the oxide film 5sc and the HfAlON film 28p (high dielectric constant film 5hp), the AlO film 29 (cap film 6p), and a gate electrode (gate electrode 7) made of a film stack of the TiN film 33 (lower gate electrode 7D) and the polycrystalline Si film (upper gate electrode 7U) is formed.

In the I/O nMIS formation region, a gate having an Nch stack gate structure comprised of a gate insulating film (gate insulating film 5nio) made of a film stack of the oxide film 5sio and the HfLaON film 28n (high dielectric constant film 5hn), the LaO film 32 (cap film 6n), and a gate electrode (gate electrode 7) made of a film stack of the TiN film 33 (lower gate electrode 7D) and the polycrystalline Si film 34 (upper gate electrode 7U) is formed. In addition, in the I/O pMIS formation region, a gate having a Pch stack gate structure comprised of a gate insulating film (gate insulating film 5pio) made of a film stack of the oxide film 5sio and the HfAlON film 28p (high dielectric constant film 5hp), the AlO film 29 (cap film 6p), and a gate electrode (gate electrode 7) made of a film stack of the TiN film 33 (lower gate electrode 7D) and the polycrystalline Si film 34 (upper gate electrode 7U) is formed.

Further, in the n-channel type resistive element formation region, a gate having an Nch gate structure comprised of a gate insulating film (gate insulating film 5nc) made of the HfLaON film 28n (high dielectric constant film 5hn) and a gate electrode (gate electrode 7) made of a polycrystalline Si film 34 (upper gate electrode 7U) is formed, while in the p-channel type resistive element formation region, a gate having a Pch gate structure comprised of a gate insulating film (gate insulating film 5pc) made of the HfAlON film 28p (high dielectric constant film 5hp) and a gate electrode (gate electrode 7) made of the polycrystalline Si film 34 (upper gate electrode 7U) is formed.

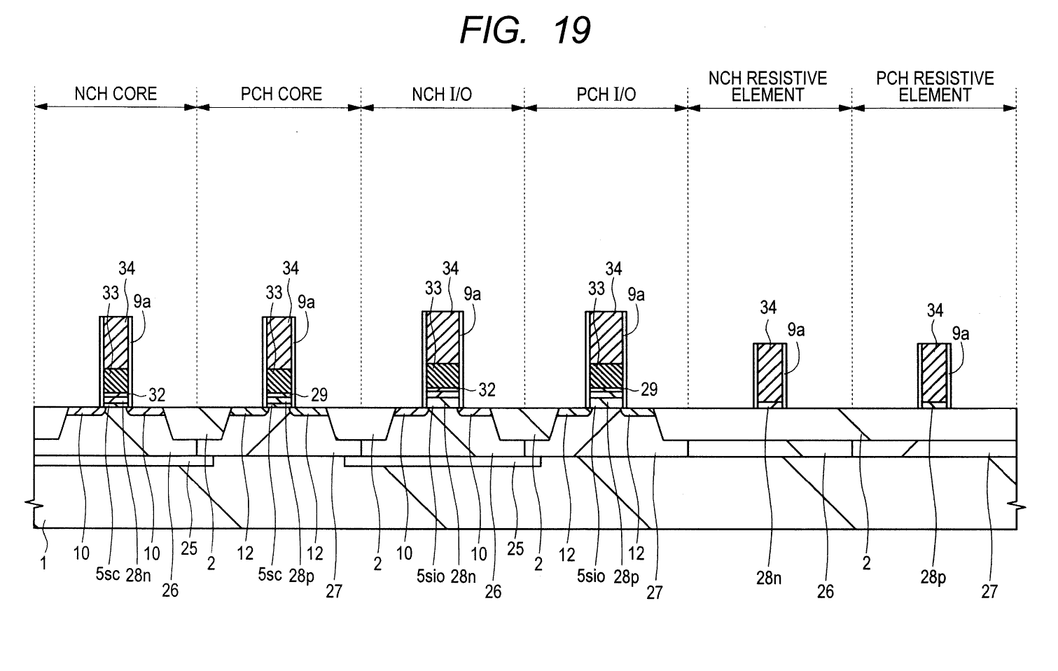

Next, as illustrated in FIG. 19, an offset sidewall 9a made of, for example, a Si₃N₄ film is formed on the side walls of the gate of each of the core nMIS, the core pMIS, the I/O nMIS, the I/O pMIS, the n-channel type resistive element, and the p-channel type resistive element. The offset sidewall 9a is formed using, for example, CVD and it has a thickness of, for example, approximately 5 nm. Then, n type diffusion regions 10 are formed in the core nMIS formation region and the I/O nMIS formation region in self alignment with the gate by using ion implantation. The n type diffusion regions 10 are semiconductor regions and are formed by introducing an n type impurity such as P or As into the semiconductor substrate 1. At the same time, p type diffusion regions 12 are formed in the core pMIS formation region and the I/O pMIS formation region in self alignment with the gate. The p type diffusion regions 12 are semiconductor regions and are formed by introducing a p type impurity such as B into the semiconductor substrate 1.

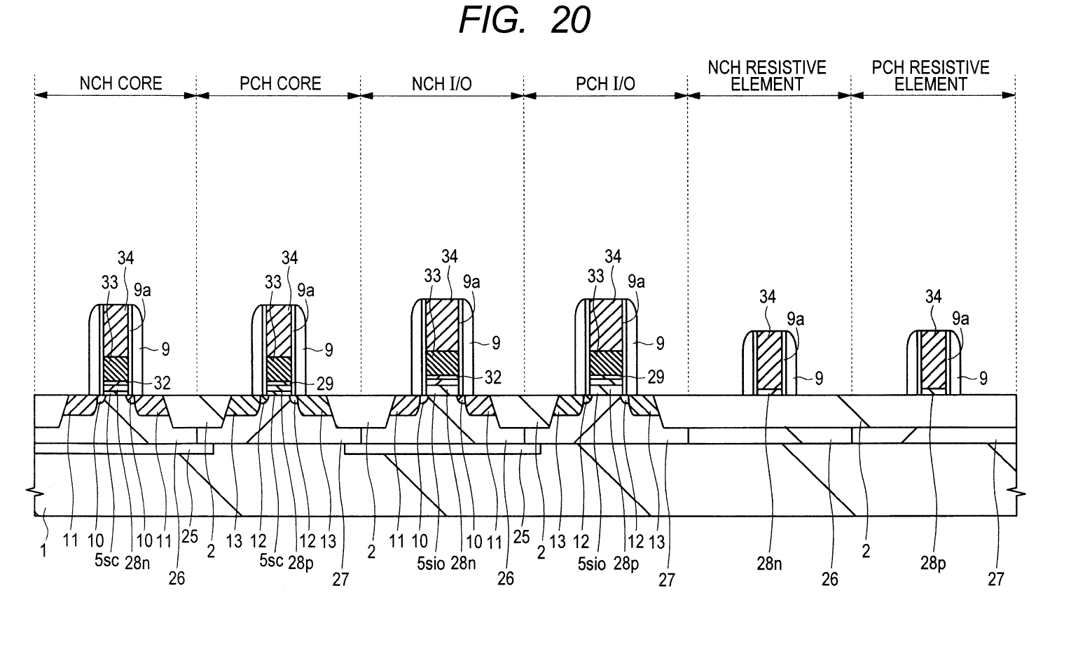

Next, as illustrated in FIG. 20, after successive deposition of a Si₃N₄ film and a SiO₂ film on the main surface of the semiconductor substrate 1, these Si₃N₄ film and SiO₂ film are anisotropically etched using dry etching. By this dry etching, a sidewall 9 is formed on the side walls of the gate of each of the core nMIS, core pMIS, I/O nMIS, I/O pMIS, n-channel type resistive element, and p-channel type resistive element.

Then, by using ion implantation, n type diffusion regions 11 are formed in the core nMIS formation region and the I/O nMIS formation region in self alignment with the gate and the sidewall 9. The n type diffusion regions 11 are semiconductor regions and are formed by introducing an n type impurity such as P or As into the semiconductor substrate 1. Similarly, p type diffusion regions 13 are formed in the core pMIS formation region and the I/O pMIS formation region in self alignment with the gate and the side wall 9. The p type diffusion regions 13 are semiconductor regions and are formed by introducing a p type impurity such as B into the semiconductor substrate 1.

Then, heat treatment is performed. This heat treatment is performed, for example, at 1000° C. for 10 seconds and 1230° C. for several milliseconds. This heat treatment activates the n type impurity introduced into the n type diffusion regions 10 and the n type diffusion regions 11 in the core nMIS formation region and the n type impurity introduced into the n type diffusion regions 10 and the n type diffusion regions 11 in the I/O nMIS formation region to form a source region and a drain region in each of these formation regions. Similarly, the heat treatment activates the p type impurity introduced into the p type diffusion regions 12 and the p type diffusion regions 13 in the core pMIS formation region and the p type impurity introduced into the p type diffusion regions 12 and the p type diffusion regions 13 in the I/O pMIS formation region to form a source region and a drain region in each of these formation regions.

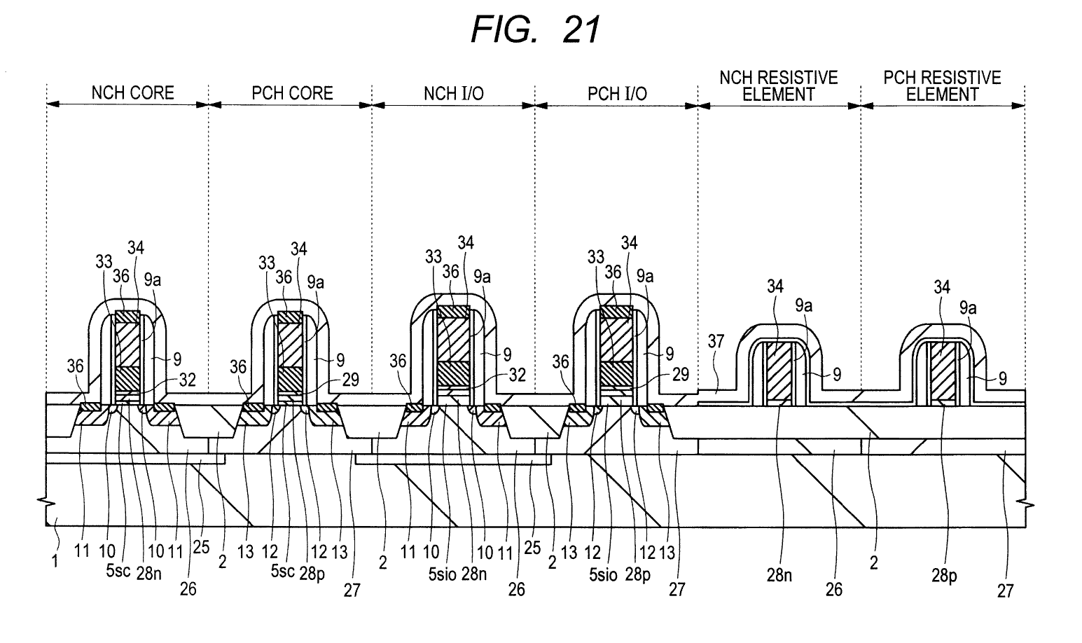

Next, as illustrated in FIG. 21, a Ni film is formed on the main surface of the semiconductor substrate 1, followed by heat treatment. This heat treatment is performed, for example, at 450° C. This heat treatment causes a solid-phase reaction between Si and Ni configuring the semiconductor substrate 1 and Si and Ni configuring the polycrystalline Si film 34 to form NiSi. Then, unreacted Ni is removed using a mixed solution of H₂SO₄ and H₂O₂. As a result, a NiSi film 36 (silicide film 8) is formed on the surface of the n type diffusion regions 11 configuring the source region and the drain region and the upper surface of the polycrystalline Si film 34 configuring the gate electrode in the core nMIS, on the surface of the p type diffusion regions 13 configuring the source region and the drain region and the upper surface of the polycrystalline Si film 34 configuring the gate electrode in the core pMIS, on the surface of the n type diffusion regions 11 configuring the source region and the drain region and the upper surface of the polycrystalline Si film 34 configuring the gate electrode in the I/O nMIS, and on the surface of the p type diffusion regions 13 configuring the source region and the drain region and the upper surface of the polycrystalline Si film 34 configuring the gate electrode in the I/O pMIS. The NiSi film 36 may be replaced with, for example, a NiPtSi film.

It is to be noted that the NiSi film 36 is not formed on the upper surface of the polycrystalline Si film 34 configuring the gate electrode of each of the n channel-type resistive element and the p-channel type resistive element in order to increase the resistance of each of the resistive elements.

Then, a Si₃N₄ film 37 is formed on the main surface of the semiconductor substrate 1. The Si₃N₄ film 37 is formed using, for example, CVD and it has a thickness of for example approximately 30 nm.

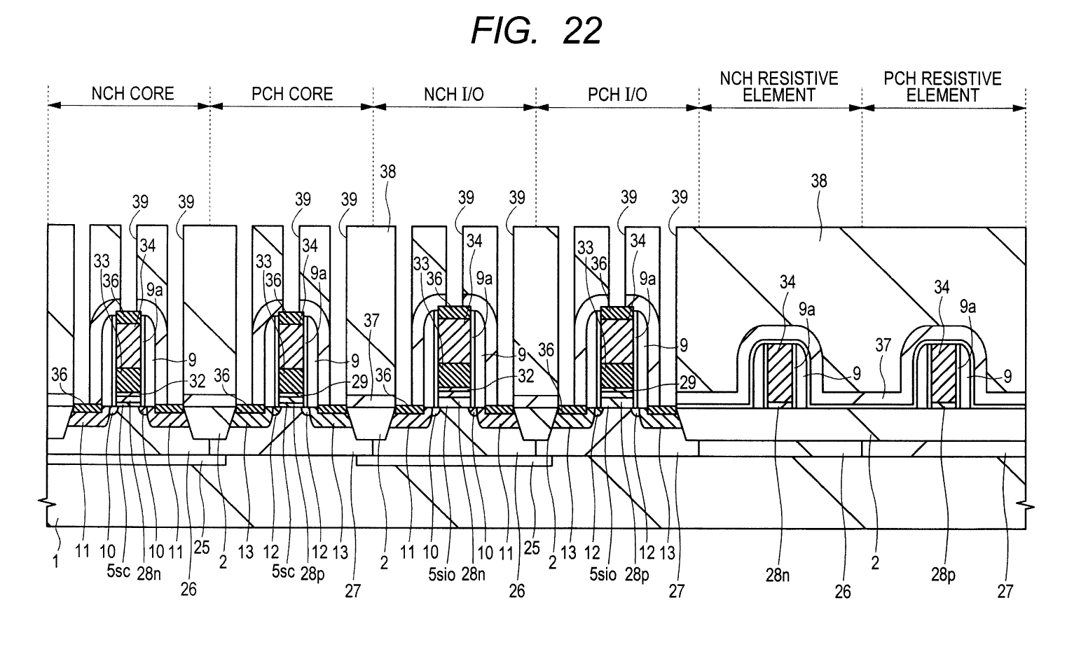

Next, as illustrated in FIG. 22, an interlayer insulating film 38 is formed on the main surface of the semiconductor substrate 1. The interlayer insulating film 38 is a TEOS film formed using, for example, plasma CVD. Then, the surface of the interlayer insulating film 38 is planarized using, for example, CMP, followed by the formation of a coupling hole 39 in the Si₃N₄ film 37 and the interlayer insulating film 38 by using photolithography and dry etching.

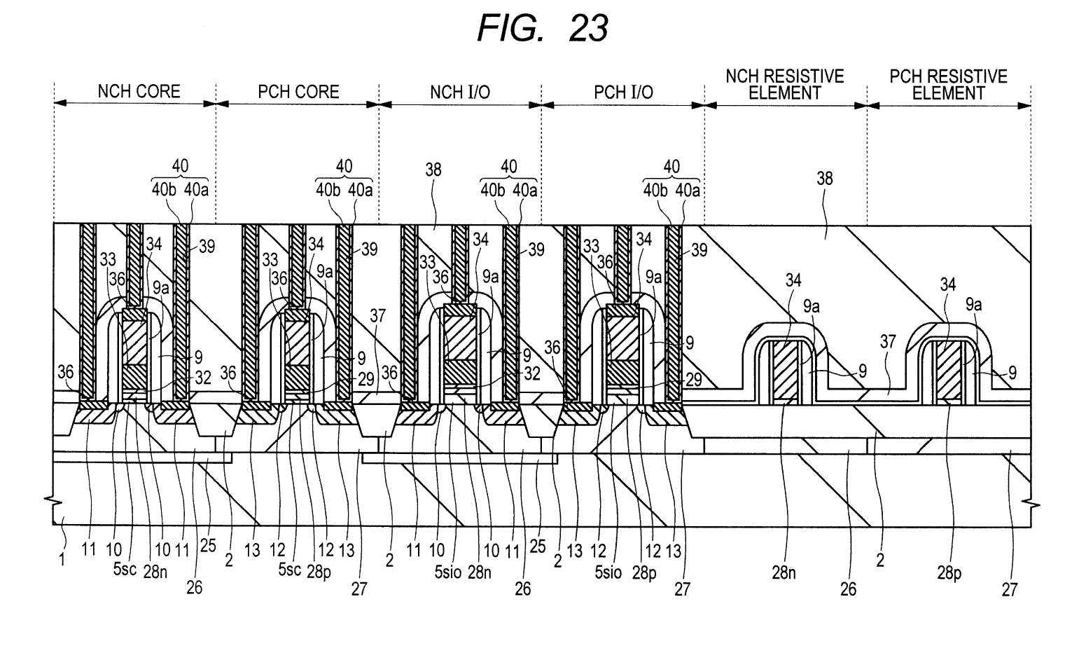

Next, as illustrated in FIG. 23, a TiN film 40a is formed on the interlayer insulating film 38 including that on the bottom surface and inner wall of the coupling hole 39 by using, for example, sputtering. The TiN film 40a is capable of preventing diffusion of a material to be buried in the coupling hole 39 in a later step and thus has a so-called barrier function. Then, a W film 40b is formed on the main surface of the semiconductor substrate 1 so as to bury the coupling hole 39 with it. This W film 40b is formed using, for example, CVD. Then, the W film 40b and the TiN film 40a are polished using, for example, CMP to form a plug 40 in the coupling hole 39.

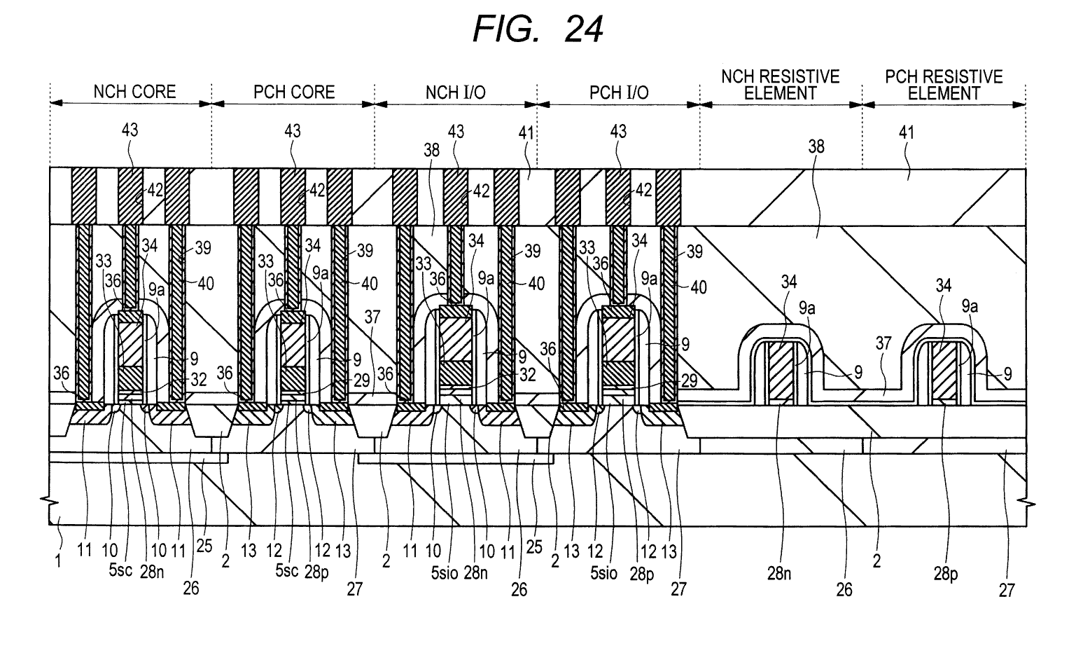

Next, as illustrated in FIG. 24, a wiring insulating film 41 is formed on the main surface of the semiconductor substrate 1. The wiring insulating film 41 is made of a film stack obtained by successively depositing, for example, a TEOS film, a SiCN film, and a SiO₂ film. A wiring trench 42 is then formed in the wiring insulating film 41 by using photolithography and dry etching.

Then, after formation of a Cu seed layer on the wiring insulating film 41 including that on the bottom surface and the inner wall of the wiring trench 42 by using, for example, sputtering, a Cu film is formed so as to bury it in the wiring trench 42 by using plating. Then, after heat treatment, the Cu film and the Cu seed layer are polished using, for example, CMP to form a wiring 43 made of the Cu film in the wiring trench 42. After that, upper-level wirings are formed but a description on them is omitted here.

By the above-described manufacturing steps, the semiconductor device according to Embodiment 1 (including core nMIS, core pMIS, I/O nMIS, I/O pMIS, n-channel type resistive element, and p-channel type resistive element) are substantially completed.

Thus, according to Embodiment 1, by forming a film stack configuring the gate G having the n-channel gate stack structure NG only in the region Ga1 which is located in the active region 14 surrounded with the element isolation portion 2 and in which the gate G of the re-channel type HK/MG transistor is to be formed, a supply amount of oxygen atoms to be attracted from the element isolation portion 2 to the region Ga1 in which the gate G of the n-channel type HK/MG transistor is to be formed can be reduced. In addition, the gate G and the element isolation portion 2 hardly overlap each other even after formation of the gate G of the n-channel type HK/MG transistor so that a supply amount of oxygen atoms from the element isolation portion 2 to the gate G of the n-channel type HK/MG transistor can be reduced. As a result, an increase in the threshold voltage of the n-channel type HK/MG transistor can be suppressed. A semiconductor device having stable operation characteristics while having such a HK/MG transistor can therefore be obtained. (Embodiment 2) A difference between an n-channel type HK/MG transistor according to Embodiment 2 and the above-described n-channel type HK/MG transistor according to Embodiment 1 is a planar layout of a gate.

In order to reduce a supply amount of oxygen atoms to be attracted from an element isolation portion to a region in which a gate of an n-channel type HK/MG transistor is to be formed, it is desired to form a film stack configuring an Nch gate stack structure only in a region located in an active region surrounded with the element isolation portion and in which the gate of the n-channel type HK/MG transistor is to be formed. In this case, as described above in Embodiment 1, however, there is a danger of the film stack configuring a Pch gate stack structure being included in a portion of the gate of the n-channel type HK/MG transistor in the actual manufacturing steps, due to misalignment or depending on processing accuracy. This may prevent the normal operation of the n-channel type HK/MG transistor.

In the n-channel type HK/MG transistor according to Embodiment 2, in the gate width direction thereof, a boundary between a film stack configuring an Nch gate stack structure and a film stack configuring a Pch gate stack structure is placed at a position which is on an element isolation portion and is, at the same time, shifted to the side of an element isolation portion from the boundary between the element isolation portion and an active region in which the n-channel type HK/MG transistor is to be formed by a distance greater than a dimension predetermined in consideration of an alignment margin in the manufacturing procedure of a semiconductor device.

On the other hand, in the gate length direction of the n-channel type HK/MG transistor, a boundary between a film stack configuring an Nch gate stack structure and a film stack configuring a Pch gate stack structure is placed at a position which is placed on an active region and is, at the same time, shifted to the side of the element isolation portion from the end portion of the gate of the n-channel type HK/MG transistor, which will be formed in a later step, by a distance equal to a dimension predetermined in consideration of an alignment margin in the manufacturing procedure of a semiconductor device.

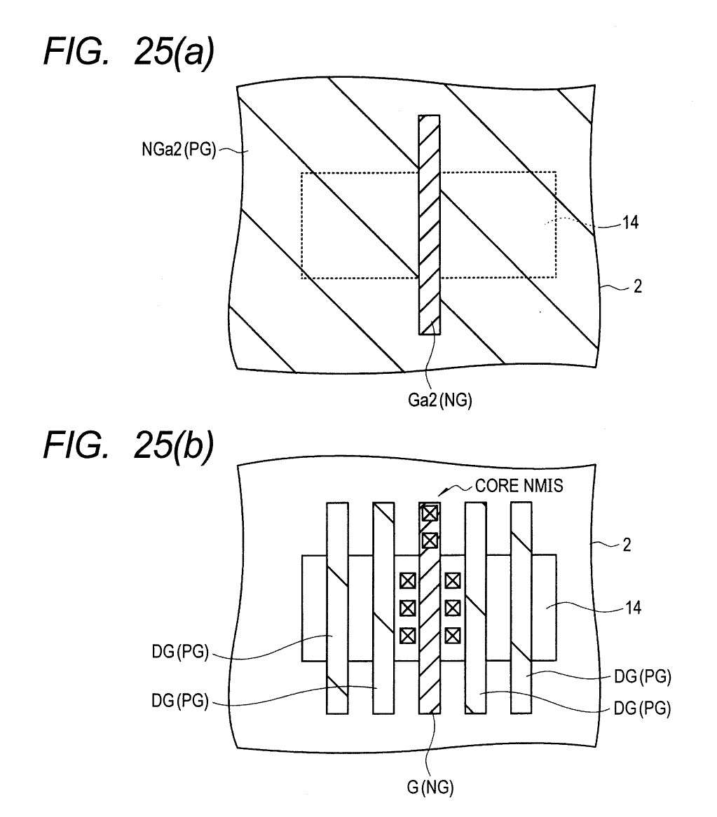

FIGS. 25(a) and 25(b) are planar layouts of a core nMIS according to Embodiment 2, in which FIG. 25(a) is a fragmentary plan view after formation of a film stack configuring a gate of the core nMIS (before processing through dry etching) and FIG. 25(b) is a fragmentary plan view after processing of the film stack configuring the core nMIS through dry etching. Here, an application example of the invention to the core nMIS is described, but it is needless to say that the invention can also be applied to an I/O nMIS.

As illustrated in FIG. 25(a), a film stack configuring an Nch gate stack structure NG is formed in a region Ga2 in which a gate will be formed in a later step continuously on an active region (region indicated by a dotted line) 14 surrounded with an element isolation portion 2 and the element isolation portion 2. On the other hand, in a region NGa2 which is a region other than the region Ga2, a film stack configuring a Pch gate stack structure PG is formed.

In the gate width direction of the core nMIS, a boundary between the region Ga2 and the region NGa2 is set at a position shifted from a boundary between the active region 14 and the element isolation portion 2 to the side of the element isolation portion 2 by a distance greater than a dimension predetermined in consideration of an alignment margin in the manufacturing procedure of a semiconductor device. The boundary between the region Ga2 and the region NGa2 is definitely on the element isolation portion 2. In the gate length direction of the core nMIS, on the other hand, a boundary between the region Ga2 and the region NGa2 is set at a position shifted from the end portion of the gate of the core nMIS to the side of the element isolation portion 2 by a distance equal to a dimension predetermined in consideration of an alignment margin in the manufacturing procedure of a semiconductor device.

FIG. 25(b) is a planar shape of each of a gate G and a dummy gate DG of the core nMIS formed by processing the film stack configuring the Nch gate stack structure NG and the film stack configuring the Pch gate stack structure PG by using dry etching.

As illustrated in FIG. 25(b), the gate G on the active region 14 and the element isolation portion 2 has the Nch gate stack structure NG. On the other hand, a plurality of the dummy gates DG formed on both sides of the gate G of the core nMIS, covering the active region 14 and the element isolation portion 2, and placed in parallel to the gate G with a predetermine distance each has the Pch gate stack structure PG.

Thus, according to Embodiment 2, a portion of the gate G having the Nch gate stack structure which the n-channel type HK/MG transistor has is on the element isolation portion 2 so that, compared with Embodiment 1, there is a higher possibility of an increase in a supply amount of oxygen atoms from the element isolation portion 2 to the gate G having the Nch gate stack structure. Compared with Embodiment 1, particularly in the gate width direction, however, there is less possibility of a portion of the gate G on the active region of the n-channel type HK/MG transistor including the film stack configuring the Pch gate stack structure PG. This makes it possible to reliably prevent malfunctions of the n-channel type HK/MG transistor due to misalignment or depending on the processing accuracy in the manufacturing steps of a semiconductor device.

### Embodiment 3

A difference between an n-channel type HK/MG transistor according to Embodiment 3 and the re-channel type HK/MG transistor according to Embodiment 1 is the structure of a gate on an element isolation portion.

On the active region surrounded with an element isolation portion, a film stack configuring an Nch gate stack structure is formed in a region in which a gate of an n-channel type HK/MG transistor is to be formed and a film stack configuring a Pch gate stack structure is formed in the other region, as in Embodiment 1. On the element isolation portion, however, a gate structure obtained by eliminating metal materials (cap film and lower gate electrode) from the Nch gate stack structure and made of a polycrystalline Si film (upper gate electrode) or a gate structure obtained by eliminating metal materials (cap film and lower gate electrode) from the Pch gate stack structure and made of a polycrystalline Si film (upper gate electrode) is used. Since the polycrystalline Si film is effective for adsorbing oxygen atoms thereto, it can reduce a supply amount of oxygen atoms to be attracted from the element isolation portion to the gate having the Nch gate stack structure which the n-channel type HK/MG transistor has.

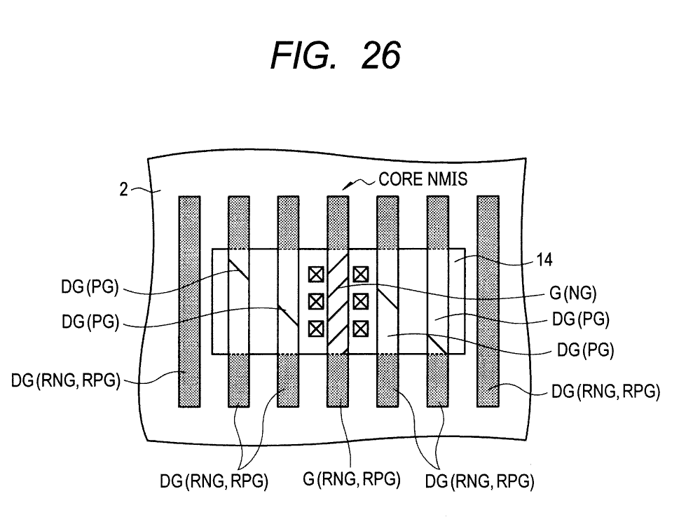

FIG. 26 is a planar layout of a core nMIS according to Embodiment 3. FIG. 26 is a fragmentary plan view after processing of a film stack configuring a gate of the core nMIS by using dry etching. Here, an application example of the invention to the core nMIS will be described, but it is needless to say that the invention can be applied also to an I/O nMIS.

As illustrated in FIG. 26, a gate G of the core nMIS located in the active region 14 surrounded with the element isolation portion 2 has an Nch gate stack structure NG similar to that of the core nMIS illustrated in FIGS. 2 and 3 made of the gate insulating film 5nc (film stack of the oxide film 5sc and the high dielectric constant film 5hn), the cap film 6n, and the gate electrode 7 (film stack of the lower gate electrode 7D and the upper gate electrode 7U). On the other hand, a plurality of dummy gates DG located in the active region 14 surrounded with the element isolation portion 2, formed on both sides of the gate of the core nMIS, and arranged in parallel to the gate G with a predetermined distance has a Pch gate stack structure PG similar to that of the core pMIS illustrated in FIGS. 2 and 3 made of the gate insulating film 5pc (film stack of the oxide film 5sc and the high dielectric constant film 5hp), the cap film 6p, and the gate electrode 7 (film stack of the gate electrode 7D and the upper gate electrode 7U).

For a gate G and a dummy gate DG of the core nMIS on the element isolation portion 2, however, employed is an Nch gate structure RNG obtained by eliminating metal materials, that is, the cap film 6n and the lower gate electrode 7D from the Nch gate stack structure NG or a Pch gate structure RPG obtained by eliminating metal materials, that is, the cap film 6p and the lower gate electrode 7D from the Pch gate stack structure PG.

The Nch gate structure RNG is similar to the gate structure of the n-channel type resistive element illustrated in FIG. 5 comprised of the gate insulating film 5nc (high dielectric constant film 5hn) and the gate electrode 7 (upper gate electrode 7U) and the Pch gate structure RPG is similar to the gate structure of the p-channel type resistive element illustrated in FIG. 5 comprised of the gate insulating film 5pc (high dielectric constant film 5hp) and the gate electrode 7 (upper gate electrode 7U). This means that as the gate G and the dummy gate DG of the core nMIS on the element isolation portion 2, employed is a gate of the n-channel type resistive element having the Nch gate structure RNG or a gate of the p-channel type resistive element having the Pch gate structure RPG.

Accordingly, the gate G of the core nMIS located in the active region 14 is comprised of, for example, the gate insulating film 5nc made of a film stack of a SiO₂ film and a HfLaON film, the cap film 6n made of a LaO film, and the gate electrode 7 made of a film stack of a TiN film and a polycrystalline Si film. The dummy gate DG located in the active region 14 is comprised of, for example, the gate insulating film 5pc made of a HfAlON film, the cap film 6p made of an AlO film, and the gate electrode 7 made of a film stack of a TiN film and a polycrystalline Si film. On the other hand, the gate G and the dummy gate DG of the core nMIS on the element isolation portion 2 is comprised of, for example, the gate insulating film 5nc made of a HfLaON film and the gate electrode 7 made of a polycrystalline Si film or the gate insulating film 5pc made of a HfAlON film and the gate electrode 7 made of a polycrystalline Si film.

Thus in Embodiment 3, in the active region 14 surrounded with the element isolation portion 2 and in which the gate G of the n-channel type HK/MG transistor is to be formed, a film stack configuring the gate G having an Nch gate stack structure is formed and in the other region, a film stack configuring the gate G having a Pch gate stack structure PG is formed. Further, on the element isolation portion 2, a gate structure obtained by removing metal materials from the Nch gate stack structure NG and made of a polycrystalline Si film or a gate structure obtained by removing metal materials from the Pch gate stack structure PG and made of a polycrystalline Si film is formed. This makes it possible to reduce the supply amount of oxygen atoms to be attracted from the element isolation portion 2 to the region in which the gate G of the n-channel type HK/MG transistor is to be formed and thereby prevent an increase in the threshold voltage of the n-channel type HK/MG transistor.

### Embodiment 4

The structure of the HK/MG transistor to be applied to the invention is not limited to the core transistor or the I/O transistor described above in Embodiment 1. A difference between a core transistor and an I/O transistor according to Embodiment 4 and the core transistor and the I/O transistor according to Embodiment 1 is a gate structure. In the core transistor and the I/O transistor according to Embodiment 4, a gate electrode of each of them is comprised of a metal film.

In Embodiment 4, the nMIS of each of the core transistor and the I/O transistor has a gate having an Nch gate stack structure comprised of a gate insulating film having a film stack of an oxide film (SiO₂ film) and a high dielectric constant film (HfLaON film), a cap film (LaO film), and a gate electrode having a film stack of a lower gate electrode (TiN film), a middle gate electrode (a pMIS work-function-controlling metal film) and an upper gate electrode (metal film). The pMIS of each of the core transistor and the I/O transistor has a gate having a Pch gate stack structure comprised of a gate insulating film having a film stack of an oxide film (SiO₂ film) and a high dielectric constant film (HfON film) and a gate electrode having a film stack of a middle gate electrode (a pMIS work-function-controlling metal film) and an upper gate electrode (metal film).

The invention can also be applied to the HK/MG transistor having a gate electrode made only of a metal film and an advantage similar to that obtained in Embodiment 1 can be achieved.

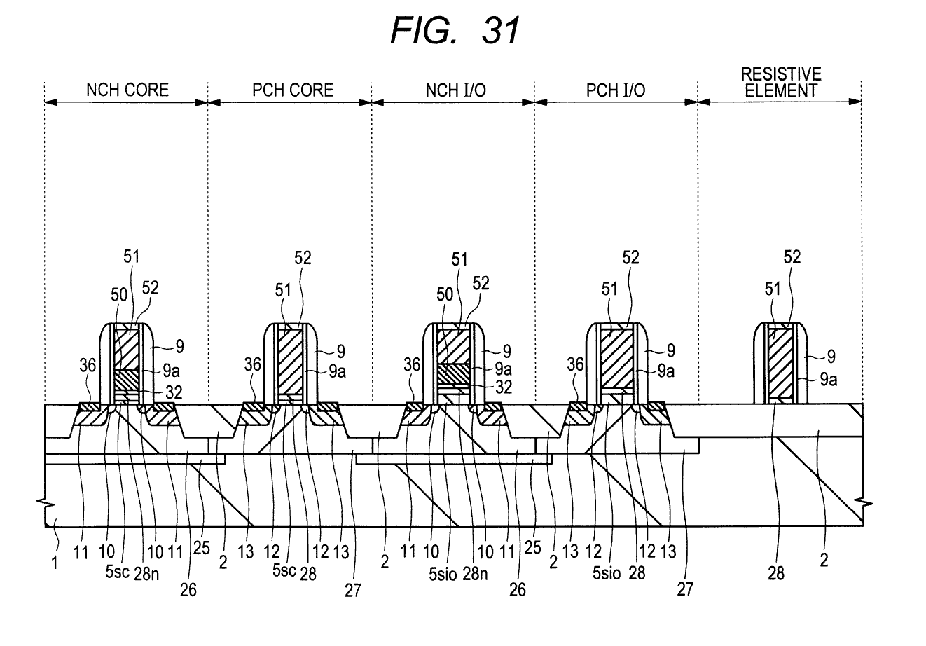

A manufacturing method of a semiconductor device according to Embodiment 4 will next be described in the order of steps referring to FIGS. 31 to 37. FIGS. 31 to 37 are fragmentary cross-sectional views, in the gate length direction, of a core nMIS (Nch Core), a core pMIS (Pch Core), an I/O nMIS (Nch I/O), an I/O pMIS (Pch I/O), and a resistive element (resistive element) among circuit elements formed in the semiconductor device.

First, by a manufacturing step similar to that of Embodiment 1, an element isolation portion 2 is formed in a semiconductor substrate 1. Active regions are separated by this element isolation portion 2 and a core nMIS formation region, a core pMIS formation region, an I/O nMIS formation region, and an I/O pMIS formation region are formed. Then, a buried n well 25, p well 26, and n well 27 are formed.

Further, as illustrated in FIG. 31, in the core nMIS formation region, a gate insulating film made of a film stack of an oxide film 5sc and a HfON film (which will be a HfLaON film 28n after heat treatment conducted later), a LaO film 32, a dummy gate electrode made of a TiN film 50 and a polycrystalline Si film 51, and a dummy gate comprised of a dummy insulating film 52 are formed. In the core pMIS formation region, a gate insulating film having a film stack of an oxide film 5sc and a HfON film 28, a dummy gate electrode made of a polycrystalline Si film 51, and a dummy gate comprised of a dummy insulating film 52 are formed.

In the I/O nMIS formation region, a gate insulating film having a film stack of an oxide film 5sio and a HfON film (which will be a HfLaON film 28n by heat treatment conducted later), a LaO film 32, a dummy gate electrode made of a TiN film 50 and a polycrystalline Si film 51, and a dummy gate comprised of a dummy insulating film 52 are formed. In the I/O pMIS formation region, a gate insulating film made of a film stack having an oxide film 5sio and a HfON film 28, a dummy gate electrode made of a polycrystalline Si film 51, and a dummy gate comprised of a dummy insulating film 52 are formed.

In the resistive element region, a gate insulating film made of a HfON film 28, a gate electrode made of a polycrystalline Si film 51 and a gate comprised of a dummy insulating film 52 are formed.

Next, an offset sidewall 9a made of, for example, a Si₃N₄ film or a SiO₂ film is formed on the side walls of the dummy gate of each of the core nMIS, core pMIS, I/O nMIS, and I/O pMIS and the gate of the resistive element. Then, n type diffusion regions 10 are formed in the core nMIS formation region and I/O nMIS formation region in self alignment with the dummy gate and offset sidewall 9a. Similarly, in the core pMIS formation region and I/O pMIS formation region, p type diffusion regions 12 are formed in self alignment with the dummy gate and offset sidewall 9a.

Next, a sidewall 9 is formed on the side walls of the dummy gate of each of the core nMIS, core pMIS, I/O nMIS, and I/O pMIS, and the gate of the resistive element via the offset sidewall 9a. Then, n type diffusion regions 11 are formed in the core nMIS formation region and the I/O nMIS formation region in self alignment with the dummy gate and the sidewall 9. Similarly, p type diffusion regions 13 are formed in the core pMIS formation region and the I/O pMIS formation region in self alignment with the dummy gate and the sidewall 9.

Next, heat treatment is performed. This heat treatment activates an n type impurity introduced into the n type diffusion regions 10 and the n type diffusion regions 11 to form a source region and a drain region of each of the core nMIS and the I/O nMIS, while it activates a p type impurity introduced into the p type diffusion regions 12 and the p type diffusion regions 13 to form a source region and a drain region of each of the core pMIS and the I/O pMIS. At the same time, this heat treatment causes thermal diffusion of La from the LaO film 32 to the HfON film to convert the HfON film in the core nMIS formation region and the I/O nMIS formation region into a HfLaON film 28n. The heat treatment may be performed so as to leave the LaO film 32. Alternatively, the heat treatment may be performed so as to cause reaction of an entirety of the LaO film 32. In the drawings after that, a portion of the LaO film 32 remains.

Next, a NiSi film 36 is formed on the surface of each of the source region and the drain region. The NiSi film 36 may be replaced with, for example, a NiPtSi film.

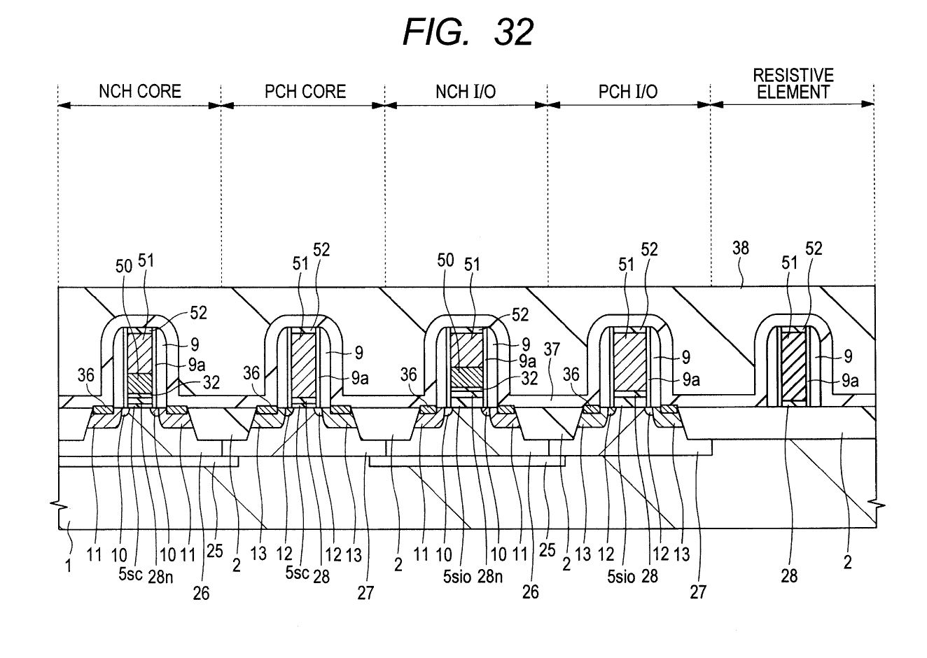

Next, as illustrated in FIG. 32, a Si₃N₄ film 37 is deposited on the main surface of the semiconductor substrate 1. The Si₃N₄ film 37 is formed using, for example, CVD. Then, an interlayer insulating film 38 is formed on the Si₃N₄ film 37 and its surface is planarized using, for example, CMP. The interlayer insulating film 38 is a TEOS film formed using, for example, plasma CVD.

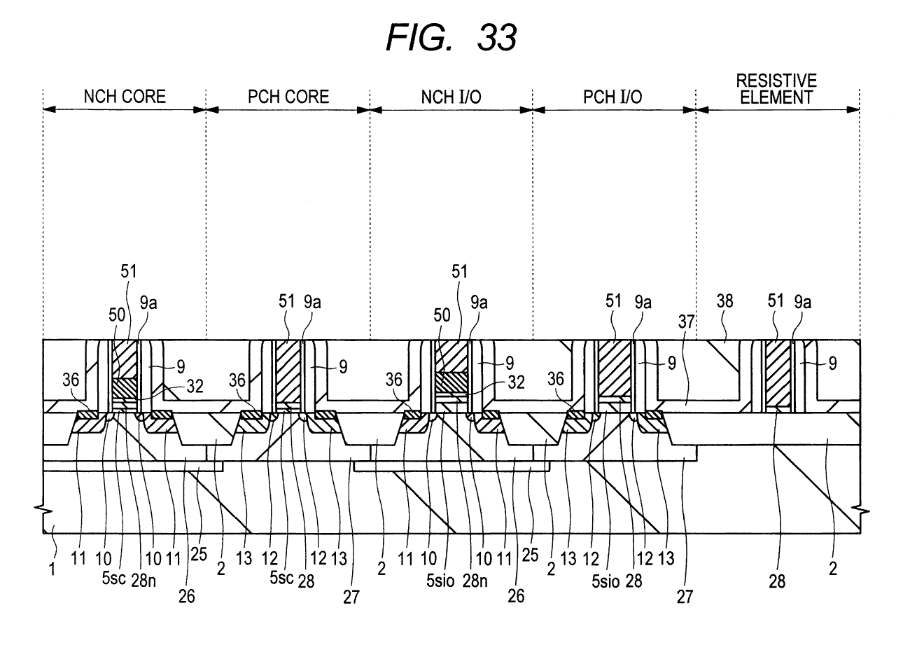

Next, as illustrated in FIG. 33, the interlayer insulating film 38, the Si₃N₄ film 37, and the dummy insulating film 52 are polished using, for example, CMP until exposure of the polycrystalline Si film 51.

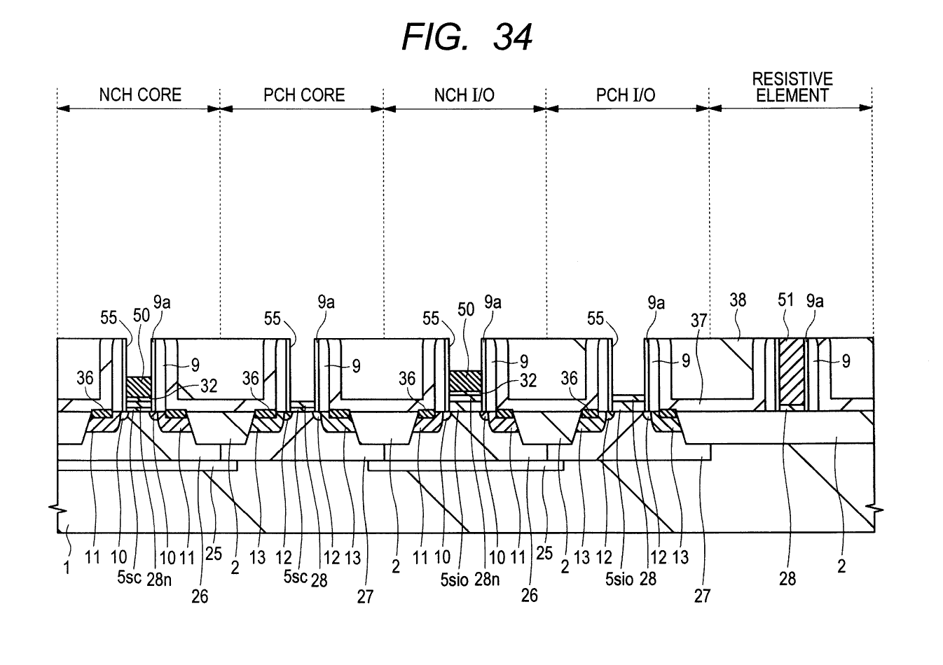

Next, as illustrated in FIG. 34, the polycrystalline Si film 51 is removed from the core nMIS formation region, the core pMIS formation region, the I/O nMIS formation region, and the I/O pMIS formation region. At the time of removal, the resistive element region is covered with a resist film or the like. By this removal, a concave portion 55 is formed at a position where the dummy gate has been formed in each of the core nMIS formation region, the core pMIS formation region, the I/O nMIS formation region, and the I/O pMIS formation region and the polycrystalline Si film 51 in the resistive element region remains. From the bottom surface of the concave portion 55 in each of the core nMIS formation region and the I/O nMIS formation region, the TiN film 50 is exposed, while the HfON film 28 is exposed from the bottom surface of the concave portion 55 in each of the core pMIS formation region and the I/O pMIS formation region.

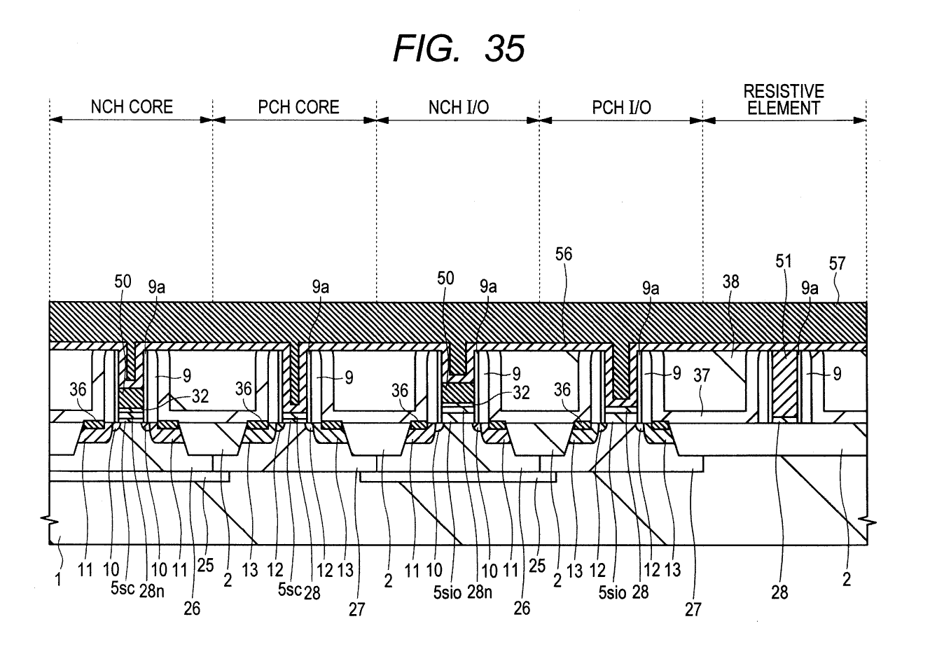

Next, as illustrated in FIG. 35, a first metal film 56 for controlling the work function of each of the core pMIS and the I/O pMIS is deposited on the main surface of the semiconductor substrate 1. The first metal film 56 is, for example, a TiN film. It has a thickness of, for example, 15 nm which is not enough for completely burying the concave portion 55. Then, a second metal film 57 is formed on the first metal film 56 so as to bury the concave portion 55. The second metal film 57 is a metal film containing, for example, Al and it has a thickness of, for example, 100 nm.

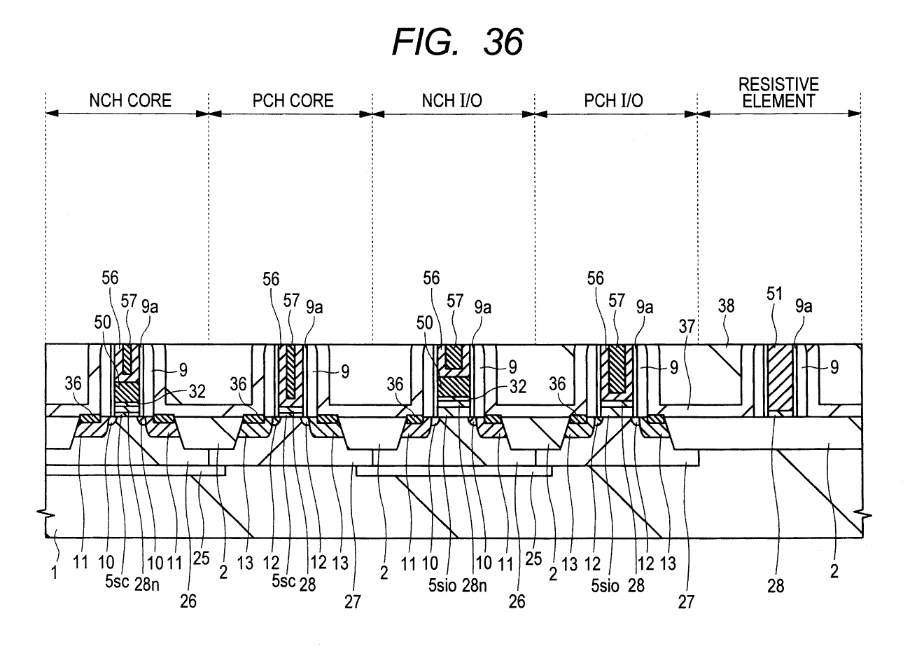

Next, as illustrated in FIG. 36, the first metal film 56 and the second metal film 57 are polished using, for example, CMP to bury the first metal film 56 and the second metal film 57 in the concave portion 55.

As a result, a gate having an Nch gate stack structure comprised of a gate insulating film having a film stack of the oxide film 5sc and the HfLaON film 28n (high dielectric constant film), the LaO film 32 (cap film), and a gate electrode having a film stack of the TiN film 50 (lower gate electrode), the first metal film 56 (middle gate electrode) and the second metal film 57 (upper gate electrode) is formed in the core nMIS formation region. A gate having a Pch gate stack structure comprised of a gate insulating film having a film stack of the oxide film 5sc and the HfON film 28 (high dielectric constant film) and a gate electrode having a film stack of the first metal film 56 (middle gate electrode) and the second metal film 57 (upper gate electrode) is formed in the core pMIS formation region.

In the I/O nMIS formation region, a gate having an Nch gate stack structure comprised of a gate insulating film having a film stack of the oxide film 5sio and the HfLaON film 28n, the LaO film 32, and a gate electrode having a film stack of the TiN film 50, the first metal film 56, and the second metal film 57 is formed. In addition, in the I/O pMIS formation region, a gate having a Pch gate stack structure comprised of a gate insulating film having a film stack of the oxide film 5sio and the HfON film 28 and a gate electrode having a film stack of the first metal film 56 and the second metal film 57 is formed.

In the resistive element formation region, a gate having an Nch gate structure comprised of a gate insulating film made of the HfON film 28 and a gate electrode made of the polycrystalline Si film 51 is formed.

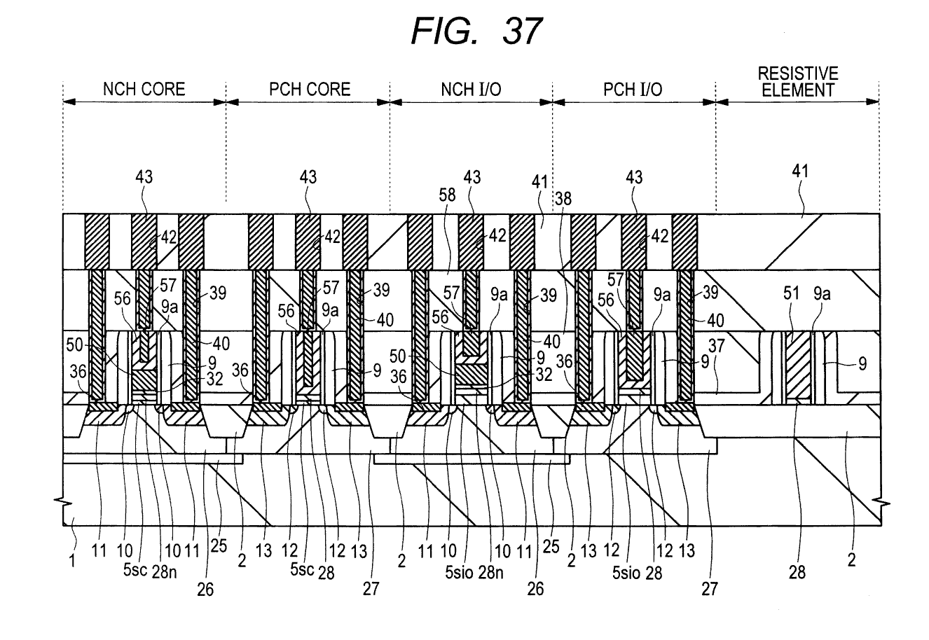

Next, as illustrated in FIG. 37, after formation of an interlayer insulating film 58 on the main surface of the semiconductor substrate 1, a coupling hole 39 is formed in the interlayer insulating films 38 and 58 and the Si₃N₄ film 37 by using photolithography and dry etching. Then, after formation of a plug 40 in the coupling hole 39, a wiring 43 is formed. Then, upper-level wirings are formed, but the description on them is omitted herein.

By the above-described manufacturing steps, a semiconductor device (core nMIS, core pMIS, I/O nMIS, I/O pMIS, and resistive element) according to Embodiment 4 is substantially completed.

Inventions made by the present inventors have been described specifically based on some embodiments. The invention is not limited to these embodiments and it is needless to say that it can be modified without departing from the gist of the invention.

The invention can be applied to a semiconductor device having a HK/MG transistor equipped with a gate insulating film comprised of a high-k material having a high dielectric constant and a gate electrode comprised of a metal material; and manufacture of the device.

1. A semiconductor device having an n-channel field effect transistor, comprising:
an element isolation portion formed on the main surface of a semiconductor substrate and having an insulating film containing oxygen atoms;
an active region formed on the main surface of the semiconductor substrate and surrounded with the element isolation portion;
a gate electrode having a predetermined gate width formed continuously over the active region and the element isolation portion;
a first insulating film formed between the gate electrode and the active region and containing La and Hf;
a second insulating film formed between the gate electrode and the element isolation portion and containing Hf but containing no La or containing La at a lower concentration than the first insulating film;
a channel region formed in the active region below the gate electrode; and
a source region and a drain region formed in the active region on both sides of the gate electrode and showing an n-type conductivity,
the semiconductor device further comprising:
a dummy gate formed in parallel to the gate electrode with a predetermined distance and partially formed on the active region between the end portion, in the gate length direction of the gate electrode, of the gate electrode and the element isolation portion; and
the second insulating film formed between the dummy gate and the active region and containing Hf but containing no La or containing La at a lower concentration than the first insulating film.

2. The semiconductor device according to claim 1,
wherein the active region and the first insulating film have therebetween an oxide film.

3. The semiconductor device according to claim 1,
wherein the first insulating film and the gate electrode have therebetween a LaO film and the second insulating film and the gate electrode have therebetween an AlO film.

4. The semiconductor device according to claim 1,
wherein the first insulating film and the second insulating film have a higher dielectric constant than SiO₂.

5. The semiconductor device according to claim 1,
wherein the gate electrode has a film stack obtained by stacking a polycrystalline Si film over a metal film.

6. The semiconductor device according to claim 1,
wherein a boundary between the first insulating film and the second insulating film in a gate width direction of the gate electrode is over the element isolation portion.

7. The semiconductor device according to claim 1, wherein the gate electrode formed over the active region has a film stack obtained by stacking a polycrystalline Si film over a metal film and the gate electrode formed over the element isolation portion has a polycrystalline Si film.

8. The semiconductor device according to claim 1,
wherein the gate electrode and the dummy gate formed over the active region each has a film stack obtained by stacking a polycrystalline Si film over a metal film and the gate electrode and the dummy gate formed over the element isolation portion have a polycrystalline Si film.

9. A manufacturing method of a semiconductor device for fabricating an n-channel type field effect transistor, comprising the steps of:
(a) forming, around an active region on the main surface of a semiconductor substrate, an element isolation portion having an oxygen-containing insulating film;
(b) forming a first oxide film over the surface of the active region;
(c) after the step (b), forming a Hf-containing third insulating film over the active region and the element isolation portion;
(d) forming a La-containing first cap film over the third insulating film in a first region of the active region having a first width in which a gate electrode is to be formed in a later step;
(e) forming an Al-containing second cap film in a second region which is a region in the active region but other than the first region and a third region in which the element isolation portion has been formed;
(f) carrying out heat treatment to diffuse La contained in the first cap film into the third insulating film of the first region and thereby form a first insulating film containing La and Hf and diffuse Al contained in the second cap film into the third insulating film of the second region and the third region and thereby form a second insulating film containing Al and Hf;
(g) successively forming a metal film and a polycrystalline Si film over the first insulating film and the second insulating film;
(h) carrying out etching to form a gate electrode having the polycrystalline Si film and the metal film continuously over the active region and the element isolation portion, form between the gate electrode and the active region of the first region a first gate insulating film having the first insulating film and the first oxide film, and form between the gate electrode and the element isolation portion a second gate insulating film having the second insulating film; and
(i) introducing an impurity into the active regions on both sides of the gate electrode to form a source region and a drain region, respectively.

10. The manufacturing method of a semiconductor device according to claim 9,
wherein the step (h) further comprises a step of:
(h1) by the etching, forming a dummy gate having the polycrystalline Si film and the metal film continuously over the active region and the element isolation portion and at the same time, in parallel to the gate electrode with a predetermined distance, forming between the dummy gate and the active region of the second region a third gate insulating film having the second insulating film and the first oxide film, and forming the second gate insulating film having the second insulating film between the dummy gate and the element isolation portion.

11. The manufacturing method of a semiconductor device according to claim 9,
wherein the first insulating film and the second insulating film each has a dielectric constant greater than SiO₂.

12. The manufacturing method of a semiconductor device according to claim 9,
wherein a boundary between the first insulating film and the second insulating film in a gate width direction of the gate electrode is over the element isolation portion.

13. The manufacturing method of a semiconductor device according to claim 9,
wherein a boundary between the first insulating film and the second insulating film in a gate width direction of the gate electrode is at a position shifted from a boundary between the active region and the element isolation portion to the side of the element isolation portion by a distance equal to a dimension predetermined in consideration of an alignment margin.

14. The manufacturing method of a semiconductor device according to claim 9,
wherein a boundary between the first insulating film and the second insulating film in a gate width direction of the gate electrode is at a position shifted from a boundary between the active region and the element isolation portion to the side of the element isolation portion by a distance greater than a dimension predetermined in consideration of an alignment margin.

15. The manufacturing method of a semiconductor device according to claim 9,
wherein the first width of the first region in a gate length direction of the gate electrode is a sum of a width of the gate electrode in a gate length direction and a dimension predetermined in consideration of an alignment margin.

16. A manufacturing method of a semiconductor device for fabricating an n-channel field effect transistor comprising the steps of:
(a) forming an element isolation portion having an oxygen-containing insulating film around an active region on the main surface of a semiconductor substrate;
(b) forming a first oxide film over the surface of the active region;
(c) after the step (b), forming a Hf-containing third insulating film over the active region and the element isolation portion;
(d) forming a La-containing first cap film on the third insulating film in a first region of the active region having a first width in which a gate electrode is to be formed in a later step;
(e) forming an Al-containing second cap film over the third insulating film in a second region which is in the active region but other than the first region and in a third region in which the element isolation portion has been formed;
(f) carrying out heat treatment to diffuse La contained in the first cap film into the third insulating film of the first region to form a first insulating film containing La and Hf and diffuse Al contained in the second cap film into the third insulating film of the second region and the third region to form a second insulating film containing Al and Hf;
(g) successively forming a metal film and a polycrystalline Si film over the first insulating film and the second insulating film in the active region and forming the polycrystalline Si film over the second insulating film in the element isolation portion;
(h) carrying out etching to form a gate electrode having the polycrystalline Si film and the metal film in the active region and a gate electrode having the polycrystalline Si film in the element isolation portion continuously over the active region and the element isolation portion, form a first gate insulating film having the first insulating film and the first oxide film between the gate electrode and the active region of the first region, and form a second gate insulating film having the second insulating film between the gate electrode and the element isolation portion; and
(i) introducing an impurity into the active regions on both sides of the gate electrode to form a source region and a drain region, respectively.

17. The manufacturing method of a semiconductor device according to claim 16,
wherein the step (h) further comprises a step of:
(h1) by the etching, forming a dummy gate having the polycrystalline Si film and the metal film in the active region and a dummy gate having the polycrystalline Si film in the element isolation portion continuously over the active region and the element isolation portion and at the same time, in parallel to the gate electrode with a predetermined distance, forming a third gate insulating film having the second insulating film and the first oxide film between the dummy gate and the active region of the second region, and forming the second gate insulating film having the second insulating film between the dummy gate and the element isolation portion.

18. The manufacturing method of a semiconductor device according to claim 16,
wherein the first insulating film and the second insulating film each has a dielectric constant greater than SiO₂.

19. The manufacturing method of a semiconductor device according to claim 16,
wherein a boundary between the first insulating film and the second insulating film in a gate width direction of the gate electrode is over the element isolation portion.

20. The manufacturing method of a semiconductor device according to claim 16,
wherein a boundary between the first insulating film and the second insulating film in a gate width direction of the gate electrode is at a position shifted from a boundary between the active region and the element isolation portion to the side of the element isolation portion by a distance equal to a dimension predetermined in consideration of an alignment margin.

21. The manufacturing method of a semiconductor device according to claim 16,
wherein a boundary between the first insulating film and the second insulating film in a gate width direction of the gate electrode is at a position shifted from a boundary between the active region and the element isolation portion to the side of the element isolation portion by a distance greater than a dimension predetermined in consideration of an alignment margin.

22. The manufacturing method of a semiconductor device according to claim 16,
wherein the first width of the first region in a gate length direction of the gate electrode is a sum of a width of the gate electrode in a gate length direction and a dimension determined in consideration of an alignment margin.
